(19) United States
(12) Patent Application Publication
(10) Pub. No.: US 2024/0072202 A1
(43) Pub. Date: Feb. 29, 2024

(54) SYSTEMS AND METHODS FOR LED STRUCTURES THAT INCREASE CURRENT FLOW DENSITY

(71) Applicant: Jade Bird Display (Shanghai) Limited, Shanghai (CN)

(72) Inventors: Qiming Li, Albuquerque, NM (US); Anle FANG, Shanghai (CN)

(73) Assignee: Jade Bird Display (Shanghai) Limited, Shanghai (CN)

(21) Appl. No.: 18/270,713

(22) PCT Filed: Jan. 8, 2021
(86) PCT No.: PCT/CN2021/070780

§ 371 Date: Jun. 30, 2023

(51) Int. Cl. H01L 33/14; H01L 33/44

(52) U.S. Cl. CPC H01L 33/14; H01L 33/44

(57) ABSTRACT

Epitaxial structure for micro light emitting diode (LED) includes, from bottom to top, a semiconductor substrate (102), an N-type electrical conductive layer (108), a N-type cladding layer (110), an active light emitting layer (114), a P-type cladding layer (118), and a P-type electrical conductive layer (120,122,124). The epitaxial structure for micro LED further includes an oxide layer (210) within the N-type cladding layer (110) and/or between the N-type electrical conductive layer (108) and the N-type cladding layer (110), and/or an oxide layer (410) within the P-type cladding layer (118) and/or between the P-type electrical conductive layer (120,122,124) and the P-type cladding layer (118). The oxide layer (210,410) is formed as an oxide ring, which effectively increases the PN junction current density and the light emission efficiency of the LED device. A one-time or a two-time transfer fabrication process is used to form the LED device.

### TECHNICAL FIELD

The present disclosure relates generally to light emitting diode (LED) display devices, and more particularly, to systems and fabricating methods for micro-LED semiconductor devices and structures that increase the PN junction current flow density of the LED.

### BACKGROUND

Display technologies are becoming increasingly popular in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices. With the development of Mini LED and Micro LED technology in recent years, consumer devices and applications such as augmented reality (AR), projection, heads-up display (HUD), mobile device displays, wearable device displays, and automotive displays, require LED panels with improved efficiency and resolution. For example, an AR display integrated within a goggle and positioned close to a wearer's eyes can have a dimension of a fingernail while still demanding an HD definition (1280×720 pixels) or higher.

Also, active matrix liquid-crystal displays (LCD) and organic light emitting diode (OLED) displays combined with thin-film transistor (TFT) technology are becoming increasingly popular in today's commercial electronic devices. These displays are widely used in laptop personal computers, smartphones and personal digital assistants. Millions of pixels together create an image on a display. The TFTs act as switches to individually turn each pixel on and off, rendering the pixel light or dark, which allows for convenient and efficient control of each pixel and of the entire display.

However, conventional LCD displays suffer from low light efficiency, causing high power consumption and limited battery operation time. While active-matrix organic light-emitting diode (AMOLED) display panels generally consume less power than LCD panels, an AMOLED display panel can still be the dominant power consumer in battery-operated devices. To extend battery life, it is desirable to reduce the power consumption of the display panel.

Conventional inorganic semiconductor light emitting diodes (LED) have demonstrated superior light efficiency, which makes active matrix LED displays more desirable for battery operated electronics. Arrays of driver circuitry and light emitting diodes (LEDs) are used to control millions of pixels, rendering images on the display. Both single-color display panels and full-color display panels can be manufactured according to a variety of fabrication methods.

However, the integration of thousands or even millions of micro LEDs with pixel driver circuit array is quite challenging. Various fabrication methods have been proposed. In one approach, control circuitry is fabricated on one substrate and LEDs are fabricated on a separate substrate. The LEDs are transferred to an intermediate substrate and the original substrate is removed. Then the LEDs on the intermediate substrate are picked and placed one or a few at a time onto the substrate with the control circuitry. However, this fabrication process is inefficient, costly and not reliable. In addition, there are no existing manufacturing tools for mass transferring micro LEDs. Therefore, new tools must be developed.

In another approach, the entire LED array with its original substrate is aligned and bonded to the control circuitry using metal bonding. The substrate on which the LEDs are fabricated remains in the final product, which may cause light cross-talk. Additionally, the thermal mismatch between the two different substrates generates stress at the bonding interface, which can cause reliability issues. Furthermore, multi-color display panels typically require more LEDs and different color LEDs grown on different substrate materials, compared with single-color display panels, thus making the traditional manufacturing process even more complicated and inefficient.

As such, it would be desirable to provide an LED structure for display panels that addresses one or more of the above-mentioned drawbacks, amongst others.

### SUMMARY

There is a need for improved LED designs that improve upon, and help to address one or more of the shortcomings of conventional display systems, such as those described above. In particular, there is a need for an LED device structure that can improve the light emitting efficiency, fabrication efficiency, reliability, and resolution at the same time while efficiently maintaining low power consumption.

Light emitting diode (LED) is a junction luminescent device, and the main structure of LED is a P-N junction. Under a forward bias, the P-N junction emits visual light or infrared light. The emission efficiency of the LED is dependent on the epitaxy material, the ohmic contact electrode, the chip structure, the geometric shape, and so on.

Display panels display various colors using a mixture of colors such as red, green and blue. Each of the pixels of the display panel includes sub-pixels such as red, green and blue sub-pixels. The color of a particular pixel is determined based on the superimposed color from the sub-pixels. The image formed by the display panel is dependent on the combination formed by each of the pixels.

In some embodiments, a multi-color LED device integrates at least two micro-LED structures horizontally placed in separate areas within a pixel area on the display panel. In some embodiments, multiple light emitting layers are fabricated by bonding in a stacked structure as a starting structure for the multi-color LED device. Each of the multiple light emitting layers is configured to emit a distinct color. The number of light emitting layers corresponds to the number of LED structures within the pixel area of the display panel. For example, if the multi-color LED device includes two sub-pixels, the number of stacked light emitting layers needed during the multi-color LED fabrication process is two. In another example, if the multi-color LED device includes three sub-pixels, the number of stacked light emitting layers needed during the multi-color LED fabrication process is three. In some embodiments, the multiple stacked LED structures are aligned vertically coaxially, i.e., the multiple LED structures are aligned along the same common central axis.

In some embodiments, the stacked LED structures allow the light emitted from the bottom LED structure to go through the middle LED structure and the top LED structure, and allow the light emitted from the middle LED structure to go through the top LED structure. The combined color of the stacked LED structures will be the final emitted color of the single pixel stacked LED device.

Pitch refers to the distance between the centers of adjacent pixels on a display panel. In some embodiments, the pitch can vary from about 40 microns, to about 20 microns, to about 10 microns, and/or preferably to about 5 microns or below. Many efforts have been made to reduce the pitch. A single pixel area is fixed when the pitch specification is determined.

Compared to conventional fabrication processes for micro-LED display chips, which rely on inefficient pick and place processes, the micro-LED fabrication processes disclosed herein effectively increases the light emission efficiency and reliability of the micro-LED device fabrication, simplifies the LED pixel device structure and reduces damage to the epitaxial layers of the LED device. For example, the PN junction current density is improved by confining the current through a layer oxidized at the edge or an oxidized ring. In another example, a two-time transfer process is used to fabricate the LED device that has the light emitted out from the p-side of the LED device. In addition, no substrate for the micro-LED structures remain in the final multi-color device so that cross-talk and mismatch can be reduced.

In addition, since each of the LED light emitting layers is a PN junction, in some embodiments, the relative positions, for example, up (closest to the emitting surface of the LED) and down (closest to a supporting substrate of the LED) positions of the P-type region and N-type region layers, within each of the LED light emitting layers in the stacked structure are not consistent. This allows flexibility and efficiency of the electrode connections within the multi-color LED structure.

The present disclosure includes, without limitation, the following exemplary embodiments.

Some exemplary embodiments of the present disclosure include a micro light emitting diode (LED) chip structure. The micro LED chip structure includes: a semiconductor substrate; an electrical contact layer on a surface of the semiconductor substrate; a first type of conductive layer on the semiconductor substrate; an active light emitting layer on the first type of conductive layer; and a second type of conductive layer on the active light emitting layer. In some embodiments, the thickness of the second-type of conductive layer is smaller than the thickness of the first-type of conductive layer, and the surface of the second-type of conductive layer is obtained after an organic material layer is removed.

Some exemplary embodiments of the present disclosure include a micro light emitting diode (LED) chip structure. The micro LED chip structure includes: a semiconductor substrate; an electrical contact layer on a surface of the semiconductor substrate; a first type of conductive layer on the semiconductor substrate; an active light emitting layer on the first type of conductive layer; and a second type of conductive layer on the active light emitting layer. In some embodiments, the surface of the second-type of conductive layer is obtained after an organic material layer is removed.

In some exemplary embodiments or any combination of exemplary embodiments of the micro LED chip structure, the micro LED chip structure further includes a second type of spacer layer between the active light emitting layer and the second type of conductive layer. In some embodiments, the second type of spacer layer is used for forming a PN junction structure with the active light emitting layer and the first type of conductive layer, and the second type of conductive layer includes one or more of second type of conductive transition layers.

In some exemplary embodiments or any combination of exemplary embodiments of the micro LED chip structure, the first type of conductive layer is an N-type layer, and the second type of conductive layer is a P-type layer.

In some exemplary embodiments or any combination of exemplary embodiments of the micro LED chip structure, the semiconductor substrate is an integrated circuits (IC) substrate.

In some exemplary embodiments or any combination of exemplary embodiments of the micro LED chip structure, the electrical contact layer is a metal bonding layer, and the semiconductor substrate and the first type of conductive layer are bonded together through a bonding process.

In some exemplary embodiments or any combination of exemplary embodiments of the micro LED chip structure, the second type of conductive layer is a P-type GaP layer, and the first type of conductive layer is an N-type GaAs layer.

In some exemplary embodiments or any combination of exemplary embodiments of the micro LED chip structure, the micro LED chip structure further includes a first type of cladding layer between the first type of conductive layer and the active light emitting layer.

In some exemplary embodiments or any combination of exemplary embodiments of the micro LED chip structure, the micro LED chip structure further includes an oxide layer within the first type of cladding layer.

In some exemplary embodiments or any combination of exemplary embodiments of the micro LED chip structure, the micro LED chip structure further includes an oxide layer between the first type of conductive layer and the first type of cladding layer.

In some exemplary embodiments or any combination of exemplary embodiments of the micro LED chip structure, the micro LED chip structure further includes a second type of cladding layer between the second type of conductive layer and the active light emitting layer.

In some exemplary embodiments or any combination of exemplary embodiments of the micro LED chip structure, the micro LED chip structure further includes an oxide layer within the second type of cladding layer.

In some exemplary embodiments or any combination of exemplary embodiments of the micro LED chip structure, the micro LED chip structure further includes an oxide layer between the second type of conductive layer and the second type of cladding layer.

In some exemplary embodiments or any combination of exemplary embodiments of the micro LED chip structure, the material of the oxide layer is AlₓOGa₁₋ₓAs, and x is greater or equal to 0.9 and less than 1.

In some exemplary embodiments or any combination of exemplary embodiments of the micro LED chip structure, the material of the first type of cladding layer is AlInP.

In some exemplary embodiments or any combination of exemplary embodiments of the micro LED chip structure, the second type of cladding layer includes one or more layers of AlInP, AlₓGa₁₋ₓInP (x is greater than 0 and less than 1), and GaInP.

In some exemplary embodiments or any combination of exemplary embodiments of the micro LED chip structure, the organic material layer is an ultraviolet (UV) curable bonding layer.

In some exemplary embodiments or any combination of exemplary embodiments of the micro LED chip structure, the ratio of a thickness of the second type of conductive layer to a thickness of the first type of conductive layer is 0.025 to 100.

In some exemplary embodiments or any combination of exemplary embodiments of the micro LED chip structure, the ratio of a thickness of the second type of conductive layer to a thickness of the first type of conductive layer is 1.5 to 2.

In some exemplary embodiments or any combination of exemplary embodiments of the micro LED chip structure, the micro LED chip structure further includes a second type of cladding layer between the second type of conductive layer and the active light emitting layer, wherein the second type of conductive layer includes a second type of conductive transition layer.

In some exemplary embodiments or any combination of exemplary embodiments of the micro LED chip structure, the ratio of the thickness of the second type of cladding layer to the thickness of the second type of conductive transition layer is 0.02 to 120.

In some exemplary embodiments or any combination of exemplary embodiments of the micro LED chip structure, the ratio of the thickness of the second type of cladding layer to the thickness of the second type of conductive transition layer is 1 to 2.5.

In some exemplary embodiments or any combination of exemplary embodiments of the micro LED chip structure, the second type of conductive layer comprises sequentially a lower second type of conductive transition layer, a middle second type of conductive transition layer, and an upper second type of conductive transition layer in a direction from the semiconductor substrate to the first type of conductive layer.

In some exemplary embodiments or any combination of exemplary embodiments of the micro LED chip structure, the conductivity of the lower second type of conductive transition layer is less than that of the middle second type of conductive transition layer, and the conductivity of the middle second type of conductive transition layer is less than the upper second type of conductive transition layer.

In some exemplary embodiments or any combination of exemplary embodiments of the micro LED chip structure, the second type of cladding layer includes one or more layers of AlInP, and AlₓGa₁₋ₓInP (x is greater than or equal to 0 and less than or equal to 1).

Some exemplary embodiments of the present disclosure include an epitaxial structure for a micro light emitting diode (LED). The epitaxial structure for the micro LED includes: a semiconductor substrate; an electrical conductive layer of a first conductivity type on the semiconductor substrate; a cladding layer of the first conductivity type on the electrical conductive layer of the first conductivity type; a first oxide layer within the cladding layer of the first conductivity type; an active light emitting layer on the cladding layer of the first conductivity type; a cladding layer of a second conductivity type on the active light emitting layer; and an electrical conductive layer of the second conductivity type on the cladding layer of the second conductivity type.

In some exemplary embodiments or any combination of exemplary embodiments of the epitaxial structure for the micro LED, the epitaxial structure for the micro LED further includes a second oxide layer within the cladding layer of the second conductivity type.

In some exemplary embodiments or any combination of exemplary embodiments of the epitaxial structure for the micro LED, the epitaxial structure for the micro LED further includes a second oxide layer between the cladding layer of the second conductivity type and the electrical conductive layer of the second conductivity type.

Some exemplary embodiments of the present disclosure include an epitaxial structure for a micro light emitting diode (LED). The epitaxial structure for the micro LED includes: a semiconductor substrate; an electrical conductive layer of a first conductivity type on the semiconductor substrate; a cladding layer of the first conductivity type on the electrical conductive layer of the first conductivity type; a first oxide layer between the electrical conductive layer of the first conductivity type and the cladding layer of the first conductivity type; an active light emitting layer on the cladding layer of the first conductivity type; a cladding layer of a second conductivity type on the active light emitting layer; and an electrical conductive layer of the second conductivity type on the cladding layer of the second conductivity type.

In some exemplary embodiments or any combination of exemplary embodiments of the epitaxial structure for the micro LED, the epitaxial structure for the micro LED further includes a second oxide layer between the cladding layer of the second conductivity type and the electrical conductive layer of the second conductivity type.

In some exemplary embodiments or any combination of exemplary embodiments of the epitaxial structure for the micro LED, the epitaxial structure for the micro LED further includes a second oxide layer within the cladding layer of the second conductivity type.

Some exemplary embodiments of the present disclosure include an epitaxial structure for a micro light emitting diode (LED). The epitaxial structure for the micro LED includes: a semiconductor substrate; an electrical conductive layer of a first conductivity type on the semiconductor substrate; a cladding layer of the first conductivity type on the electrical conductive layer of the first conductivity type; an active light emitting layer on the cladding layer of the first conductivity type; a cladding layer of a second conductivity type on the active light emitting layer; a first oxide layer within the cladding layer of the second conductivity type; and an electrical conductive layer of the second conductivity type on the cladding layer of the second conductivity type.

In some exemplary embodiments or any combination of exemplary embodiments of the epitaxial structure for the micro LED, the epitaxial structure for the micro LED further includes a second oxide layer within the cladding layer of the first conductivity type.

In some exemplary embodiments or any combination of exemplary embodiments of the epitaxial structure for the micro LED, the epitaxial structure for the micro LED further includes a second oxide layer between the cladding layer of the first conductivity type and the electrical conductive layer of the first conductivity type.

Some exemplary embodiments of the present disclosure include an epitaxial structure for a micro light emitting diode (LED). The epitaxial structure for the micro LED includes: a semiconductor substrate; an electrical conductive layer of a first conductivity type on the semiconductor substrate; a cladding layer of the first conductivity type on the electrical conductive layer of the first conductivity type; an active light emitting layer on the cladding layer of the first conductivity type; a cladding layer of a second conductivity type on the active light emitting layer; an electrical conductive layer of the second conductivity type on the cladding layer of the second conductivity type; and a first oxide layer between the cladding layer of the second conductivity type and the electrical conductive layer of the second conductivity type.

In some exemplary embodiments or any combination of exemplary embodiments of the epitaxial structure for the micro LED, the epitaxial structure for the micro LED further includes a second oxide layer between the cladding layer of the first conductivity type and the electrical conductive layer of the first conductivity type.

In some exemplary embodiments or any combination of exemplary embodiments of the epitaxial structure for the micro LED, the epitaxial structure for the micro LED further includes a second oxide layer within the cladding layer of the first conductivity type.

In some exemplary embodiments or any combination of exemplary embodiments of the epitaxial structure for the micro LED, the oxide layer is formed as an oxide ring from an oxide layer precursor AlₓGa₁₋ₓAs, and x is greater or equal to 0.9 and less than 1.

In some exemplary embodiments or any combination of exemplary embodiments of the epitaxial structure for the micro LED, the cladding layer of the first conductivity type includes one or more layers.

In some exemplary embodiments or any combination of exemplary embodiments of the epitaxial structure for the micro LED, the cladding layer of the second conductivity type includes one or more layers.

In some exemplary embodiments or any combination of exemplary embodiments of the epitaxial structure for the micro LED, the epitaxial structure for the micro LED further includes between the semiconductor substrate and the electrical conductive layer of the first conductivity type, sequentially a buffer layer of the first conductivity type and an etch-stop layer of the first conductivity type in a direction from the semiconductor substrate to the electrical conductive layer of the first conductivity type.

In some exemplary embodiments or any combination of exemplary embodiments of the epitaxial structure for the micro LED, the epitaxial structure for the micro LED further includes a spacer layer of the first conductivity type located on a bottom of the active light emitting layer, and a spacer layer of the second conductivity type located on a top of the active light emitting layer.

In some exemplary embodiments or any combination of exemplary embodiments of the epitaxial structure for the micro LED, the electrical conductive layer of the second conductivity type comprises one or more conductive transition layers.

In some exemplary embodiments or any combination of exemplary embodiments of the epitaxial structure for the micro LED, the electrical conductive layer of the second conductivity type comprises sequentially a lower conductive transition layer of the second conductivity type, a middle conductive transition layer of the second conductivity type, and an upper conductive transition layer of the second conductivity type in a direction from the semiconductor substrate to the electrical conductive layer of the first conductivity type.

In some exemplary embodiments or any combination of exemplary embodiments of the epitaxial structure for the micro LED, the conductivity of the lower conductive transition layer of the second conductivity type is less than that of the middle conductive transition layer of the second conductivity type, and the conductivity of the middle conductive transition layer of the second conductivity type is less than the upper conductive transition layer of the second conductivity type.

In some exemplary embodiments or any combination of exemplary embodiments of the epitaxial structure for the micro LED, the material of the first oxide layer is AlₓOGa₁₋ₓAs, and x is greater or equal to 0.9 and less than 1.

In some exemplary embodiments or any combination of exemplary embodiments of the epitaxial structure for the micro LED, the material of the cladding layer of the first conductivity type is AlInP.

In some exemplary embodiments or any combination of exemplary embodiments of the epitaxial structure for the micro LED, the material of the cladding layer of the second conductivity type includes one or more layers of AlInP, and AlₓGa₁₋ₓInP (x is greater than or equal to 0 and less than or equal to 1).

The compact design of the LED devices and systems disclosed herein utilizes the bonding layers and introduces intermediate substrate(s), thereby reducing the complexity of the fabrication steps and increase the overall performance to cost ratio of the LED display systems. Furthermore, the fabrication of the LED display systems can reliably and efficiently form the LED structure patterns without retaining extra substrates. Thus, implementation of the multi-color LED display systems can satisfy the rigorous display requirements for AR and VR, heads-up displays (HUD), mobile device displays, wearable device displays, high definition small projectors, and automotive displays compared with the use of the conventional LEDs.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

FIG. 1 is a cross-sectional view of an LED structure, in accordance with some embodiments.

FIG. 2A is a cross-sectional view of an LED structure with an oxide precursor layer within the n-cladding layer, in accordance with some embodiments.

FIG. 2B is a cross-sectional view of an LED structure with an oxide layer within the n-cladding layer, in accordance with some embodiments.

FIG. 3A is a cross-sectional view of an LED structure with an oxide precursor layer between the n⁺-contact layer and the n-cladding layer, in accordance with some embodiments.

FIG. 3B is a cross-sectional view of an LED structure with an oxide layer between the n+-contact layer and the n-cladding layer, in accordance with some embodiments.

FIG. 4A is a cross-sectional view of an LED structure with an oxide precursor layer within the p-cladding layer, in accordance with some embodiments.

FIG. 4B is a cross-sectional view of an LED structure with an oxide layer within the p-cladding layer, in accordance with some embodiments.

FIG. 5A is a cross-sectional view of an LED structure with an oxide precursor layer between the p-cladding layer and the p-transition layer 120, in accordance with some embodiments.

FIG. 5B is a cross-sectional view of an LED structure with an oxide layer between the p-cladding layer and the p-transition layer, in accordance with some embodiments.

FIGS. 6A-6D illustrate a fabrication process utilizing a one-time transfer process to form an LED structure with a supporting substrate with integrated circuits, in accordance with some embodiments.

FIGS. 7A-7H illustrate a fabrication process utilizing a two-time transfer process to form an LED structure with a supporting substrate with integrated circuits, in accordance with some embodiments.

FIG. 8 is a top view of a micro LED display panel, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

Embodiments consistent with the disclosure include a display panel, including a substrate with an array of pixel driver circuits, an array of LEDs with structures described below, formed over the substrate, and methods of making the display panel. The display panels having a high light extraction efficiency are capable of overcoming the drawbacks of the conventional display systems.

Generally, at least red, green and blue colors are superimposed to reproduce a broad array of colors. In some instances, to include at least red, green and blue colors within a pixel area, separate monochromatic LED structures are fabricated at different non-overlapping zones within the pixel area.

In some embodiments, three LEDs, are formed in a stacked structure, for example, starting from a base layer formed by a substrate, the green LED is directly on top of the red LED, and the blue LED is directly on top of the green LED. In some embodiments, the light emitted from the red LED is able to propagate through the green LED and then through the blue LED to be emitted out of the tri-color LED device. In some embodiments, the light emitted from the green LED is able to propagate through the blue LED to be emitted out of the tri-color LED device. In other embodiments, the color of the monochromatic LEDs are not limited to red, green and blue and can be any other visible or invisible colors. In other embodiments, the monochromatic LEDs' order from bottom (closest to the substrate) to top (closest to the emitting surface of the LED) are not limited to red, green and blue colors.

In some embodiments, a single pixel area on a display panel includes at least one single pixel light emitting device, such as an LED or a micro-LED, or an OLED, and light is emitted from the LED. The LED has a top surface and a bottom surface. In some embodiments, the diameter or width of the top surface of the LED is in the range of 1 μm-8 μm, and the diameter or width of the bottom surface of the LED is in the range of 3 μm-10 μm. In some embodiments, the diameter or width of the top surface of the LED is in the range of 8 μm-25 μm, and the diameter or width of the bottom surface of the LED is in the range of 10 μm-35 μm. In some embodiments, the height of the LED is in the range of 1-10 μm. In some embodiments, the height of the LED is about 1.3 μm. In some embodiments, the diameter or width of the top surface of the LED is equal to or less than the diameter or width of the bottom surface of the LED.

In some embodiments, a display panel includes an array of single pixel LEDs. In some embodiments, the distance between center axes of the two adjacent LEDs is in the range of 1 μm-10 μm. In some embodiments, the distance between center axes of the two adjacent LEDs may vary from about 40 μm, to about 20 μm, to about 10 μm, and/or to about 5 μm or below. In some embodiments, sizes of the mesas and distances between the LEDs may depend on the resolution of the display. For example, for a display panel with 5000 Pixels Per Inch (PPI), the diameter or width of the top surface of the LED is 1.5 μm and the diameter or width of the bottom surface of the LED is 2.7 μm. In some embodiments, the distance between the closest bottom edges of two adjacent LEDs may be in the range of 1 μm-10 μm. In some embodiments, the distance between the closest bottom edges of two adjacent LEDs is 2.3 μm.

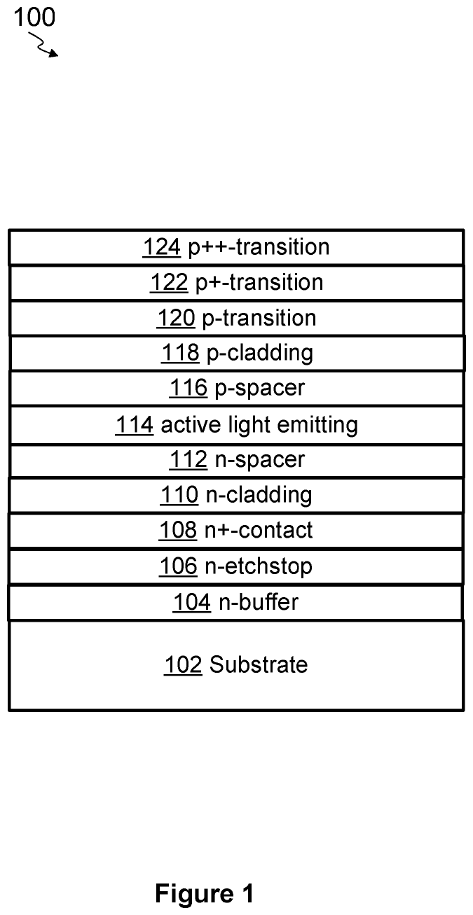

FIG. 1 is a cross-sectional view of an LED structure 100, in accordance with some embodiments. In some embodiments, the LED structure 100 is for forming one of the three color LED devices within a pixel area in a display panel. In some embodiments, the three color LED devices include three color LED structures, such as 100. Each of the three color LED structures forms a sub-pixel within the single pixel area. In some embodiments, the three color LED structures each emit a single color, for example, blue, green, and a red. In some embodiments, the colors emitted by the three color LED structures are different and distinct. In some embodiments, the color emitted by the LED structure 100 is red.

In some embodiments, a display panel includes a plurality of pixels, such as millions of pixels, and each pixel includes a set of three color LED devices. In some embodiments, the color LED devices can be micro LEDs. Micro LEDs typically have a lateral dimension of 50 microns (um) or less, and can have lateral dimensions less than 10 um and even just a few um.

In some embodiments, the LED structure 100 includes a substrate 102. For convenience, “up” is used to mean away from the substrate 102, “down” means toward the substrate 102, and other directional terms such as top, bottom, above, below, under, beneath, etc. are interpreted accordingly.

In general, an LED color light emitting layer includes a PN junction with a p-type region/layer and an n-type region/layers, and an active layer between the p-type region/layer and n-type region/layer.

In some embodiments, the substrate 102 is made of GaAs. In some embodiments, the thickness of the substrate 102 is about 350 μm. In some embodiments, the thickness of the substrate 102 is about 325 μm to 375 μm. In some embodiments, the substrate 102 is doped with Si at a carrier concentration of 0.4×10¹⁸ to 4.0×10¹⁸ cm⁻³.

Although some features are described herein with the term “layer”, it should be understood that such features are not limited to a single layer but may include a plurality of sublayers. In some instance, a “structure” can take the form of a “layer”.

In some embodiments, the layers of the LED structure are formed from an epitaxial process, such as metal organic chemical vapor deposition (MOCVD).

In some embodiments, an n-buffer layer 104 is formed above the substrate 102. A buffer layer is formed before the subsequent layers are formed to reduce lattice growth mismatch in an epitaxial process. In some embodiments, the n-buffer layer 104 is formed by GaAs. In some embodiments, the thickness of the n-buffer layer 104 is about 200 nm. In some embodiments, the thickness of the n-buffer layer 104 is about 190 nm to 210 nm. In some embodiments, the n-buffer layer 104 is doped with Si at a carrier concentration of 1.0×10¹⁸ to 5.0×10¹⁸ cm⁻³.

In some embodiments, an n-etch stop layer 106 is formed above the n-buffer layer 104. The n-etch stop layer 106 is used in a subsequent process to prevent the etching of an n⁺-contact layer 108 in a subsequent etching process to remove the substrate 102. The n-etch stop layer 106 is not reactive to the selective etching solution for removing GaAs. In some embodiments, the n-etch stop layer 106 is formed by Al_{0.15}GaInP. In some embodiments, the thickness of the n-etch stop layer 106 is about 200 nm. In some embodiments, the thickness of the n-etch stop layer 106 is about 190 nm to 210 nm. In some embodiments, the n-etch stop layer 106 is doped with Si at a carrier concentration of 1.0×10¹⁸ to 5.0×10¹⁸ cm⁻³.

In some embodiments, the n⁺-contact layer 108 is formed above the n-etch stop layer 106. The n⁺-contact layer 108 is an n-type conductive layer. In some embodiments, the n⁺-contact layer 108 is formed by GaAs. In some embodiments, the thickness of the n⁺-contact layer 108 is about 5 nm to 200 nm. In some embodiments, the n⁺-contact layer 108 is doped with Si at a carrier concentration of 1.0×10¹⁸ to 5.0×10¹⁸ cm⁻³.

In some embodiments, an n-cladding layer 110 is formed above the n⁺-contact layer 108. The n-cladding layer 110 is used for providing and confinement of the n-type carriers in a PN junction. In some embodiments, the n-cladding layer 110 is formed by AlInP. In some embodiments, the thickness of the n-cladding layer 110 is about 100 nm to 5 μm. In some embodiments, the n-cladding layer 110 is doped with Si at a carrier concentration of 1.0×10¹⁸ to 5.0×10¹⁸ cm⁻³.

In some embodiments, an n-spacer layer 112 is formed above the n-cladding layer 110 and below an active light emitting layer 114. The n-spacer layer 112 is used as barrier layer between the n-cladding layer 110 and the active light emitting layer 114. In some embodiments, the n-spacer layer 112 is formed by Al_{0.8}GaInP. In some embodiments, the thickness of the n-spacer layer 112 is about 10 nm to 200 nm.

In some embodiments, the active light emitting layer 114 is formed above n-spacer layer 112. In some embodiments, the active light emitting layer 114 is formed as a multiple quantum well structure. In some embodiments, the active light emitting layer 114 is formed of alternative layers of AlInGaP (x is from 0 to 0.5) and Al_{0.8}InGaP, for example, a first layer of AlInGaP is formed above a first layer of Al_{0.8}InGaP, a second layer of Al_{0.8}InGaP is formed on the first layer of AlₓInGaP, and a second layer of AlₓInGaP is formed on the second layer of Al_{0.8}InGaP. In some embodiments, the active light emitting layer 114 is composed of 1 to 30 pairs of layers of AlₓInGaP (x is from 0 to 0.5) and Al_{0.8}InGaP. In some embodiments, the single layer of AlₓInGaP (x is from 0 to 0.5) is about 3.5 nm. In some embodiments, the single layer of AlₓInGaP (x is from 0 to 0.5) is about 1 to 30 nm. In some embodiments, the single layer of Al_{0.8}InGaP is about 6.5 nm. In some embodiments, the single layer of Al_{0.8}InGaP is about 1 to 30 nm.

In some embodiments, the active LED light emitting layer 114, includes many epitaxial sub-layers with different compositions. Examples of the active LED light emitting layer includes III-V nitride, III-V arsenide, III-V phosphide, and III-V antimonide epitaxial structures. Examples of active LED light emitting layers include GaN based UV/blue/green light emitting layers, AlInGaP based red/orange light emitting layers, and GaAs or InP based infrared (IR) light emitting layers.

In some embodiments, a p-spacer layer 116 is formed above the active light emitting layer 114. The p-spacer layer 116 is used as barrier layer between a p-cladding layer 118 and the active light emitting layer 114. In some embodiments, the p-spacer layer 116 is formed by Al_{0.8}GaInP. In some embodiments, the thickness of the p-spacer layer 116 is about 10 nm to 200 nm.

In some embodiments, the p-cladding layer 118 is formed above the p-spacer layer 116. The p-cladding layer 118 is used for providing and confinement of the p-type carriers in a PN juction. In some embodiments, the p-cladding layer 118 is formed by one or more layers composed of AlInP, AlₓGa_{y}InP (x changes from 1 to 0.9 and y changes from 0 to 1), and Al_{0.8}GaInP. For example, the p-cladding layer 118 is formed by three layers of AlInP, AlInP, and Al_{0.8}GaInP from bottom to top. In another example, the p-cladding layer 118 is formed by three layers of AlInP, Al_{0.9}GaInP, and Al_{0.8}GaInP from bottom to top. Yet in another example, the p-cladding layer 118 is formed by a bottom layer composed of AlInP, a top layer composed of AlₓGa₁₋ₓInP (from bottom to up, the layer composition gradually changes, i.e. x changes from 0 to 1). In some examples, the p-cladding layer 118 is formed by multiple groups of layers of AlInP, and AlₓGa₁₋ₓInP (x changes from 0 to 1), periodically. In some embodiments, the thickness of the p-cladding layer 118 is about 100 nm to 5 μm. In some embodiments, the p-cladding layer 118 is doped with Mg at a carrier concentration of 1.0×10¹⁷ to 9.0×10¹⁷ cm⁻³.

In some embodiments, a p-transition layer 120 is formed above the p-cladding layer 118. In some embodiments, the p-transition layer 120 is formed by Al_{0.17}GaInP. In some embodiments, the thickness of the p-transition layer 120 is about 20 nm to 100 nm. In some embodiments, the p-transition layer 120 is doped with Mg at a carrier concentration of greater than 1.0×10¹⁸ cm⁻³ and less than 2.0×10¹⁸ cm⁻³.

In some embodiments, a p⁺-transition layer 122 is formed above the p-transition layer 120. In some embodiments, the p⁺-transition layer 122 is formed by GaP. In some embodiments, the thickness of the p⁺-transition layer 122 is about 10 nm to 5 μm. In some embodiments, the p⁺-transition layer 122 is doped with Mg at a carrier concentration of 2.0×10¹⁸ to 9.0×10¹⁸ cm⁻³. The doping concentration of the p⁺-transition layer 122 is higher than the doping concentration of the p-transition layer 120.

In some embodiments, a p⁺⁺-transition layer 124 is formed above the p⁺-transition layer 122. In some embodiments, the p⁺⁺-transition layer 124 is formed by GaP. In some embodiments, the thickness of the p⁺⁺-transition layer 124 is about 10 nm to 30 nm. In some embodiments, the p⁺⁺-transition layer 124 is doped with Carbon at a carrier concentration of 1.0×10¹⁹ to 9.0×10¹⁹ cm⁻³. The doping concentration of the p⁺⁺-transition layer 124 is higher than the doping concentration of the p⁺-transition layer 122. The gradual elevation of the doping concentration can stabilize the growth of the p-transition layers and prevent or ease defect and stress formed from the lattice change.

The p-type conductive layers include layers such as the p-transition layer 120, p⁺-transition layer 122, and p⁺⁺-transition layer 124.

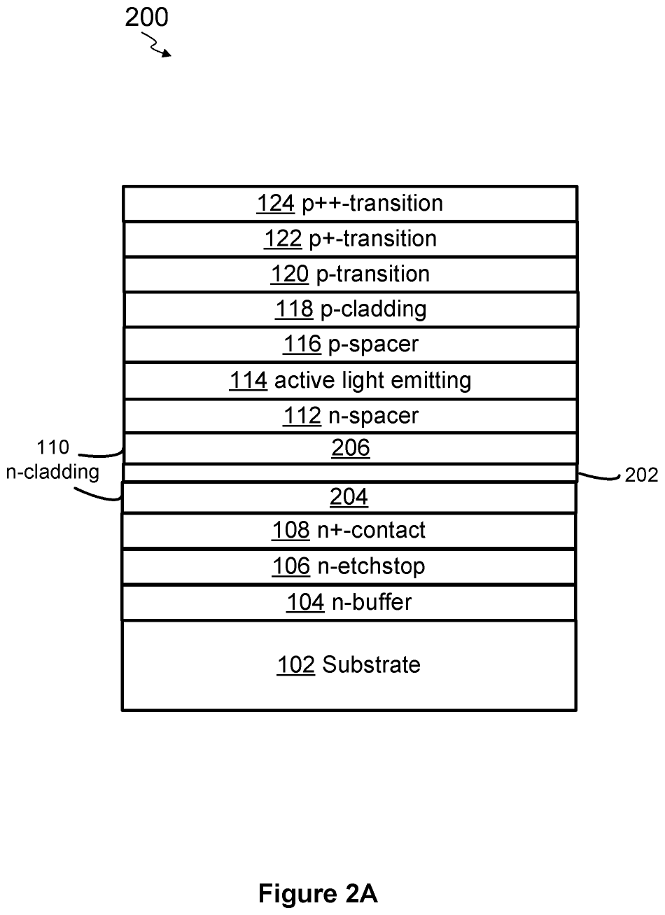

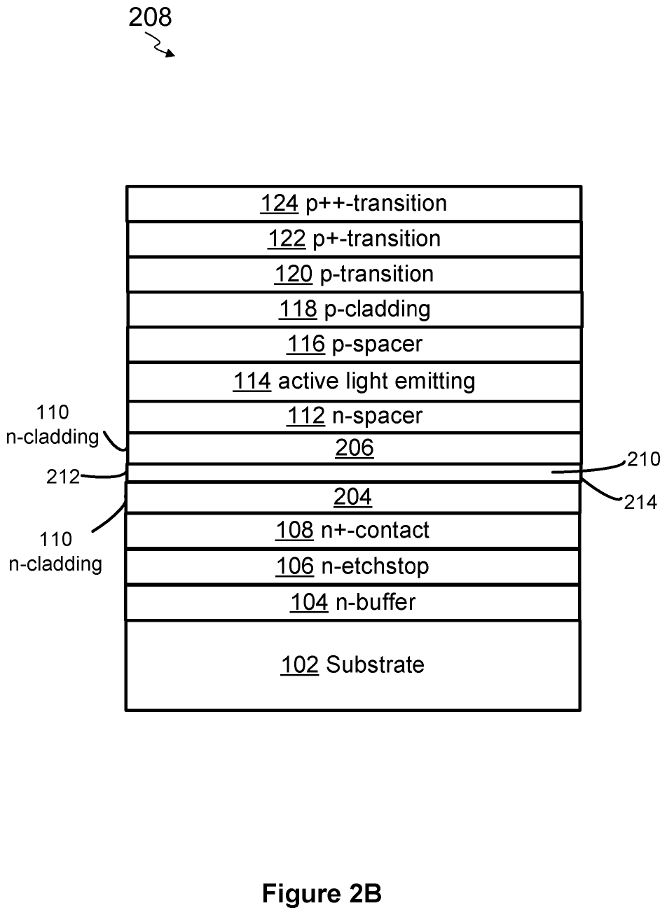

FIG. 2A is a cross-sectional view of an LED structure 200 with an oxide precursor layer 202 within the n-cladding layer 110, in accordance with some embodiments. In some embodiments, the LED structure 200 includes a layer 202 composed of AlₓGa₁₋ₓAs (x is greater than or equal to 0.9 and less than 1). In some embodiments, the thickness of the layer 202 is about 1 nm to 100 nm. The rest of the structure of the LED structure is similar or the same as all the layers of the LED structure 100 as described in FIG. 1. In some embodiments, the layer 202 is located within the n-cladding layer 110, for example, in between a first layer 204 within the n-cladding layer 110 and a second layer 206 within the n-cladding layer 110. In some embodiments, the layer 202 is used as a pre-cursor before a subsequent oxidation process. In some embodiments, the layer 202 is doped with Si at a carrier concentration of 1.0×10¹⁷ to 9.0×10¹⁸ cm⁻³.

FIG. 2B is a cross-sectional view of an LED structure 208 with an oxide layer 210 within the n-cladding layer 110, in accordance with some embodiments. In some embodiments, the LED structure 208 includes an oxide layer 210. In some embodiments, the oxide layer 210 is composed of AlₓOGa₁₋ₓAs (x is greater than or equal to 0.9 and less than 1). The rest of the structure of the LED structure 208 is similar or the same as all the layers of the LED structure 100 as described in FIG. 1. In some embodiments, the layer 210 is located within the n-cladding layer 110, for example, in between a first layer 204 within the n-cladding layer 110 and a second layer 206 within the n-cladding layer 110. In some embodiments, the oxide layer 210 is formed from an oxidation process after all the layers of the LED structure 200 as described in FIG. 2A is formed.

In some embodiments, a subsequent oxidation process is applied after all the epitaxial layers of the LED structure 200 are formed. In some embodiments, the oxidation process is a wet oxidation. In some embodiments, the wet oxidation is conducted in a wet oxygen oxidation furnace. In one example, the wet oxygen oxidation furnace is VF3000 VCSEL furnace from Koyo Thermo Systems. In some embodiments, a nitrogen gas is used as carrier gas at a flow rate of 1 liter per minute. Oxygen is obtained from the water heated at around 98° C. in the wet oxygen oxidation furnace. In some embodiments, the wet oxidation uses an ambient temperature from 380° C. to 500° C., and a time of equal to or under 2 hours. The oxidation is a controlled oxidation on the side wall of the LED structure 200. Since all the other layers in the LED structure 200 are not reactive to the oxidation process, the side wall of the layer 202 is oxidized. The oxidation process is stopped when the desired oxidation depth of the side wall of the layer 202 is reached. In some embodiments, the preferred oxidation depth of the side wall of the layer 202 is around one fourth of the lateral diameter of the layer 202. In some embodiments, the preferred oxidation depth of the side wall of the layer 202 is around one fifth of the lateral diameter of the layer 202. In some embodiments, the preferred oxidation depth of the side wall of the layer 202 is around one third of the lateral diameter of the layer 202.

In some embodiments, after the oxidation process, the oxide layer 210 composed of AlₓOGa₁₋ₓAs (x is greater than or equal to 0.9 and less than 1) is formed from the original layer 202 composed of AlₓGa₁₋ₓAs (x is greater than or equal to 0.9 and less than 1). In a preferred embodiment, the oxide layer 210 has AlₓOGa₁₋ₓAs (x is greater than or equal to 0.9 and less than 1) formed around the edge, for example, 212 and 214, of the layer of 210, i.e., toward the side of the LED structure 208, while the center of the layer 210 remains less oxidized/or remains not oxidized. In some embodiments, all the other layers in the LED structure 200/208 other than the original layer 202 composed of AlₓGa₁₋ₓAs (x is greater than or equal to 0.9 and less than 1) are resistant to the oxidation process and remain unoxidized.

Non-radiative electron-hole pair recombination at the side surface, especially, defect sites, of the n-cladding layer 110 may cause additional energy loss, such as heat, and reduce the light emission efficiency. The introduction of the oxide layer 210 within the n-cladding layer 110 can reduce the surface non-radiative recombination and improve the light emission efficiency of the LED device. Specifically, when the oxidation mostly happens at the edge of the layer 210, the formed oxide layer can reduce or eliminate the non-radiative recombination at the side surfaces or edge, such as, locations 212 and 214, around the layer 210. The main current of an LED is in a vertical direction and there are some current diffusions to the side of the LED in the electric current flowing process. In some embodiments, when the oxidation mostly happens at the edge of the layer 210, the formed oxide layer can reduce the lateral diffusion of the electric current to the edge, and confine the electric current to the central portion of the LED device formed from the LED structure 208, therefore, increasing the effective electric current density and improving the LED light emission efficiency. In some embodiments, the light emission efficiency is at least 20%. In some embodiments, the light emission efficiency is at least 30%. In some embodiments, the light emission efficiency is at least 40%. In some embodiments, the light emission efficiency is at least 50%. In some embodiments, the light emission efficiency is at least 60%.

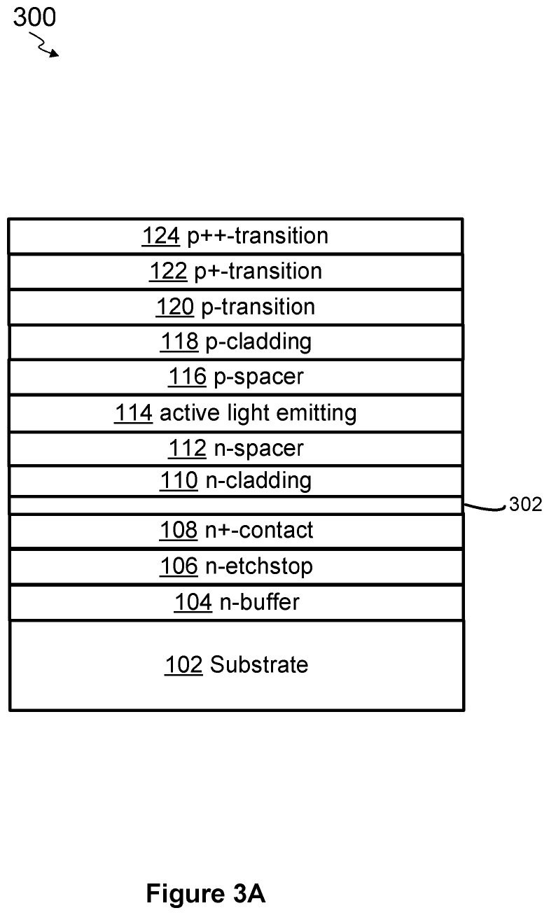

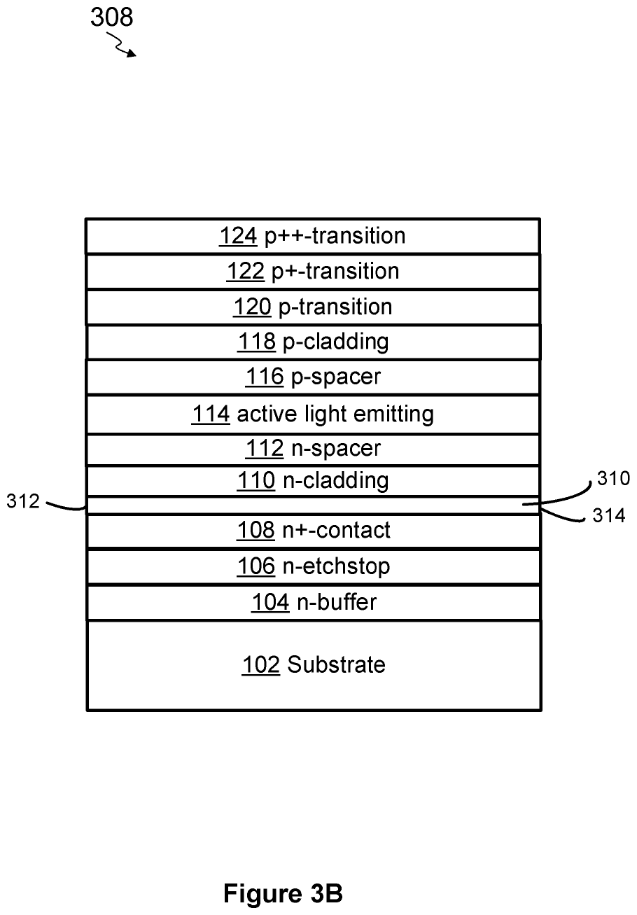

FIG. 3A is a cross-sectional view of an LED structure 300 with an oxide precursor layer 302 between the n⁺-contact layer 108 and the n-cladding layer 110, in accordance with some embodiments. In some embodiments, the LED structure 300 includes a layer 302 composed of AlₓGa₁₋ₓAs (x is greater than or equal to 0.9 and less than 1). In some embodiments, the thickness of the layer 302 is about 1 nm to 100 nm. The rest of the structure of the LED structure is similar or the same as all the layers of the LED structure 100 as described in FIG. 1. In some embodiments, the layer 302 is located between the n⁺-contact layer 108 and the n-cladding layer 110. In some embodiments, the layer 302 is used as a pre-cursor before a subsequent oxidation process. In some embodiments, the layer 302 is doped with Si at a carrier concentration of 1.0×10¹⁷ to 9.0×10¹⁸ cm⁻³.

FIG. 3B is a cross-sectional view of an LED structure 308 with an oxide layer 310 between the n⁺-contact layer 108 and the n-cladding layer 110, in accordance with some embodiments. In some embodiments, the LED structure 308 includes an oxide layer 310. In some embodiments, the oxide layer 310 is composed of AlₓOGa₁₋ₓAs (xis greater than or equal to 0.9 and less than 1). The rest of the structure of the LED structure 308 is similar or the same as all the layers of the LED structure 100 as described in FIG. 1. In some embodiments, the layer 310 is located between the n⁺-contact layer 108 and the n-cladding layer 110. In some embodiments, the oxide layer 310 is formed from an oxidation process after all the layers of the LED structure 300 as described in FIG. 3A is formed.

In some embodiments, a subsequent oxidation process is applied after all the epitaxial layers of the LED structure 300 are formed. In some embodiments, the oxidation process is a wet oxidation. In some embodiments, the wet oxidation is conducted in a wet oxygen oxidation furnace. In one example, the wet oxygen oxidation furnace is VF3000 VCSEL furnace from Koyo Thermo Systems. In some embodiments, a nitrogen gas is used as carrier gas at a flow rate of 1 liter per minute. Oxygen is obtained from the water heated at around 98° C. in the wet oxygen oxidation furnace. In some embodiments, the wet oxidation uses an ambient temperature from 380° C. to 500° C., and a time of equal to or under 2 hours. The oxidation is a controlled oxidation on the side wall of the LED structure 300. Since all the other layers in the LED structure 300 are not reactive to the oxidation process, the side wall of the layer 302 is oxidized. The oxidation process is stopped when the desired oxidation depth of the side wall of the layer 302 is reached. In some embodiments, the preferred oxidation depth of the side wall of the layer 302 is around one fourth of the lateral diameter of the layer 302. In some embodiments, the preferred oxidation depth of the side wall of the layer 302 is around one fifth of the lateral diameter of the layer 302. In some embodiments, the preferred oxidation depth of the side wall of the layer 302 is around one third of the lateral diameter of the layer 302.

In some embodiments, after the oxidation process, the oxide layer 310 composed of AlₓOGa₁₋ₓAs (x is greater than or equal to 0.9 and less than 1) is formed from the original layer 302 composed of AlₓGa₁₋ₓAs (x is greater than or equal to 0.9 and less than 1). In a preferred embodiment, the oxide layer 310 has AlₓOGa₁₋ₓAs (x is greater than or equal to 0.9 and less than 1) formed around the edge of the layer of 310, for example, 312 and 314, i.e., toward the side of the LED structure 308, while the center of the layer 310 remains less oxidized/or remains not oxidized. In some embodiments, all the other layers in the LED structure 300/308 other than the original layer 302 composed of AlₓGa₁₋ₓAs (x is greater than or equal to 0.9 and less than 1) are resistant to the oxidation process and remain unoxidized.

Non-radiative electron-hole pair recombination at the side surfaces, especially, defect sites, of the n⁺-contact layer 108 and the n-cladding layer 110 may cause additional energy loss, such as heat, and reduce the light emission efficiency. The introduction of the oxide layer 310 between the n⁺-contact layer 108 and the n-cladding layer 110 can reduce the surface non-radiative recombination and improve the light emission efficiency of the LED device. Specifically, when the oxidation mostly happens at the edge of the layer 310, the formed oxide layer can reduce or eliminate the non-radiative recombination at the side surfaces or edge, such as, locations 312 and 314, around the layer 310. The main current of an LED is in a vertical direction and there are some current diffusions to the side of the LED in the electric current flowing process. In some embodiments, when the oxidation mostly happens at the edge of the layer 310, the formed oxide layer can reduce the lateral diffusion of the electric current to the edge, and confine the electric current to the central portion of the LED device formed from the LED structure 308, therefore, increasing the effective electric current density and improving the LED light emission efficiency. In some embodiments, the light emission efficiency is at least 20%. In some embodiments, the light emission efficiency is at least 30%. In some embodiments, the light emission efficiency is at least 40%. In some embodiments, the light emission efficiency is at least 50%. In some embodiments, the light emission efficiency is at least 60%.

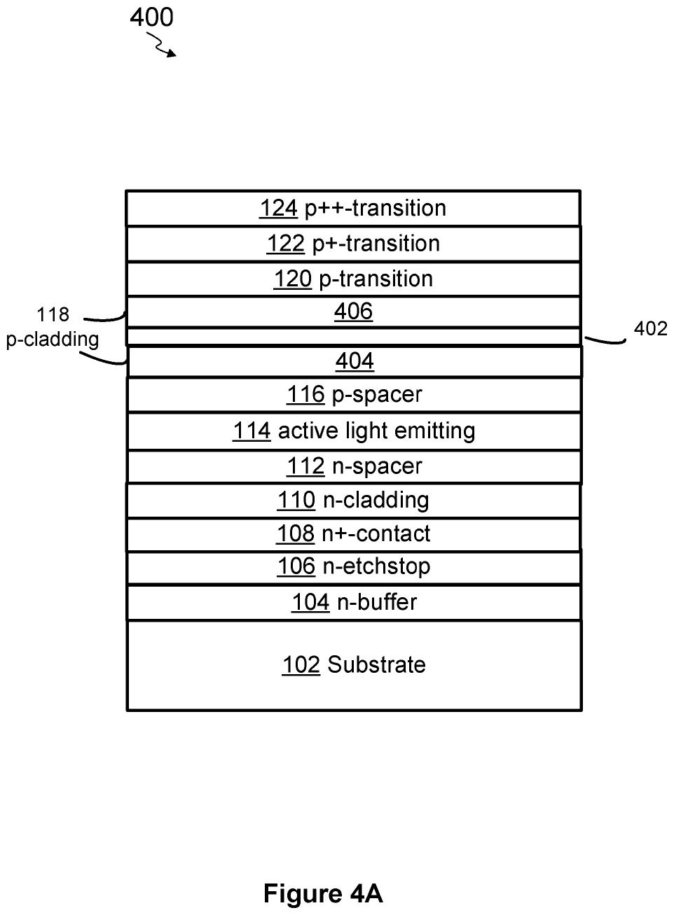

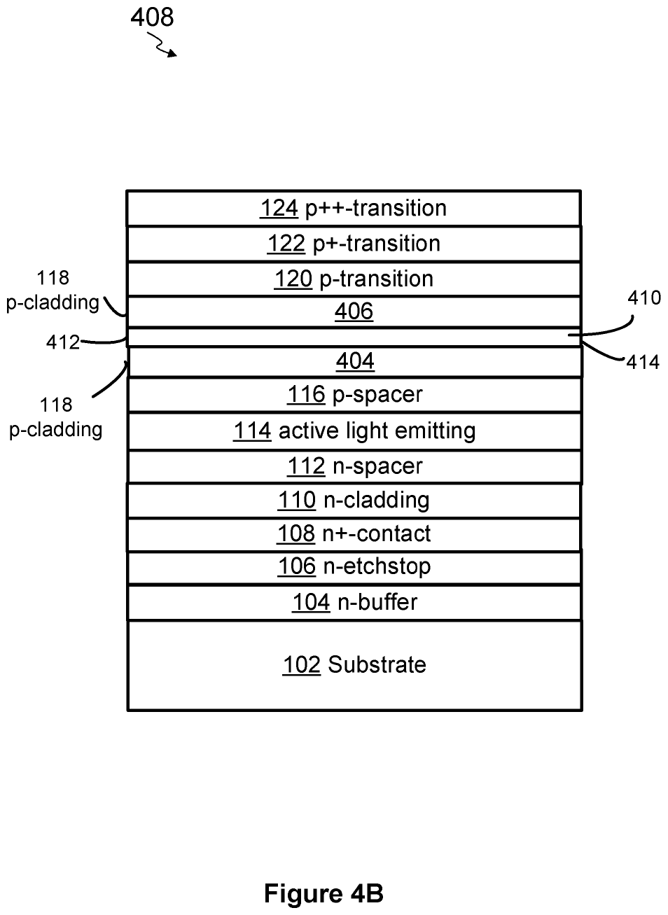

FIG. 4A is a cross-sectional view of an LED structure 400 with an oxide precursor layer 402 within the p-cladding layer 118, in accordance with some embodiments. In some embodiments, the LED structure 400 includes a layer 402 composed of AlₓGa₁₋ₓAs (x is greater than or equal to 0.9 and less than 1). In some embodiments, the thickness of the layer 402 is about 1 nm to 100 nm. The rest of the structure of the LED structure is similar or the same as all the layers of the LED structure 100 as described in FIG. 1. In some embodiments, the layer 402 is located within the p-cladding layer 118, for example, in between a first layer 404 within the p-cladding layer 118 and a second layer 406 within the p-cladding layer 118. In some embodiments, the layer 402 is used as a pre-cursor before a subsequent oxidation process. In some embodiments, the layer 402 is doped with Mg at a carrier concentration of 1.0×10¹⁷ to 9.0×10¹⁸ cm⁻³.

FIG. 4B is a cross-sectional view of an LED structure 408 with an oxide layer 410 within the p-cladding layer 118, in accordance with some embodiments. In some embodiments, the LED structure 408 includes an oxide layer 410. In some embodiments, the oxide layer 410 is composed of AlₓOGa₁₋ₓAs (x is greater than or equal to 0.9 and less than 1). The rest of the structure of the LED structure 408 is similar or the same as all the layers of the LED structure 100 as described in FIG. 1. In some embodiments, the layer 410 is located within the p-cladding layer 118, for example, in between a first layer 404 within the p-cladding layer 118 and a second layer 406 within the p-cladding layer 118. In some embodiments, the oxide layer 410 is formed from an oxidation process after all the layers of the LED structure 400 as described in FIG. 4A is formed.

In some embodiments, a subsequent oxidation process is applied after all the epitaxial layers of the LED structure 400 are formed. In some embodiments, the oxidation process is a wet oxidation. In some embodiments, the wet oxidation is conducted in a wet oxygen oxidation furnace. In one example, the wet oxygen oxidation furnace is VF3000 VCSEL furnace from Koyo Thermo Systems. In some embodiments, a nitrogen gas is used as carrier gas at a flow rate of 1 liter per minute. Oxygen is obtained from the water heated at around 98° C. in the wet oxygen oxidation furnace. In some embodiments, the wet oxidation uses an ambient temperature from 380° C. to 500° C., and a time of equal to or under 2 hours. The oxidation is a controlled oxidation on the side wall of the LED structure 400. Since all the other layers in the LED structure 400 are not reactive to the oxidation process, the side wall of the layer 402 is oxidized. The oxidation process is stopped when the desired oxidation depth of the side wall of the layer 402 is reached. In some embodiments, the preferred oxidation depth of the side wall of the layer 402 is around one fourth of the lateral diameter of the layer 402. In some embodiments, the preferred oxidation depth of the side wall of the layer 402 is around one fifth of the lateral diameter of the layer 402. In some embodiments, the preferred oxidation depth of the side wall of the layer 402 is around one third of the lateral diameter of the layer 402.

In some embodiments, after the oxidation process, the oxide layer 410 composed of AlₓOGa₁₋ₓAs (x is greater than or equal to 0.9 and less than 1) is formed from the original layer 402 composed of AlₓGa₁₋ₓAs (x is greater than or equal to 0.9 and less than 1). In a preferred embodiment, the oxide layer 410 has AlₓOGa₁₋ₓAs (x is greater than or equal to 0.9 and less than 1) formed around the edge, for example, 412 and 414, of the layer of 410, i.e., toward the side of the LED structure 408, while the center of the layer 410 remains less oxidized/or remains not oxidized. In some embodiments, all the other layers in the LED structure 400/408 other than the original layer 402 composed of AlₓGa₁₋ₓAs (x is greater than or equal to 0.9 and less than 1) are resistant to the oxidation process and remain unoxidized.

Non-radiative electron-hole pair recombination at the side surface, especially, defect sites, of the p-cladding layer 118 may cause additional energy loss, such as heat, and reduce the light emission efficiency. The introduction of the oxide layer 410 within the p-cladding layer 118 can reduce the surface non-radiative recombination and improve the light emission efficiency of the LED device. Specifically, when the oxidation mostly happens at the edge of the layer 410, the formed oxide layer can reduce or eliminate the non-radiative recombination at the side surfaces or edge, such as, locations 412 and 414, around the layer 410. The main current of an LED is in a vertical direction and there are some current diffusions to the side of the LED in the electric current flowing process. In some embodiments, when the oxidation mostly happens at the edge of the layer 410, the formed oxide layer can reduce the lateral diffusion of the electric current to the edge, and confine the electric current to the central portion of the LED device formed from the LED structure 408, therefore, increasing the effective electric current density and improving the LED light emission efficiency. In some embodiments, the light emission efficiency is at least 20%. In some embodiments, the light emission efficiency is at least 30%. In some embodiments, the light emission efficiency is at least 40%. In some embodiments, the light emission efficiency is at least 50%. In some embodiments, the light emission efficiency is at least 60%.

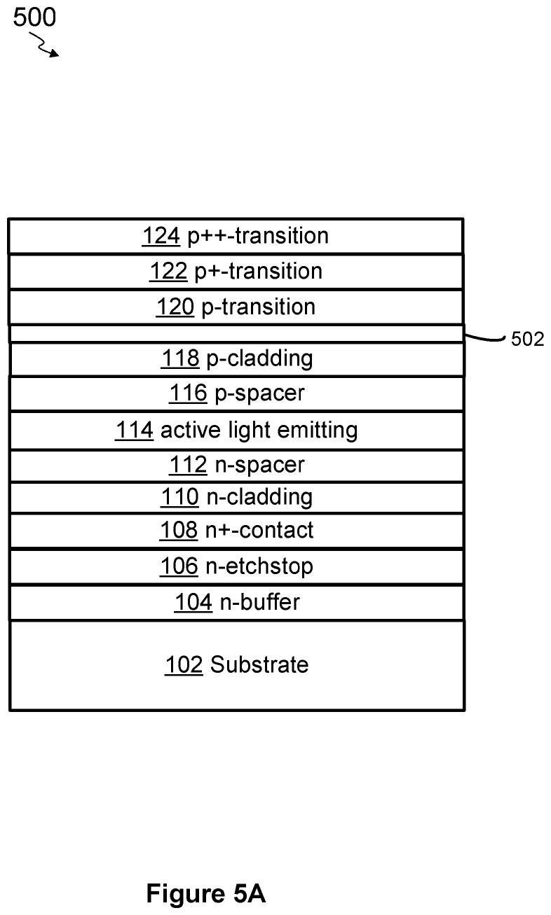

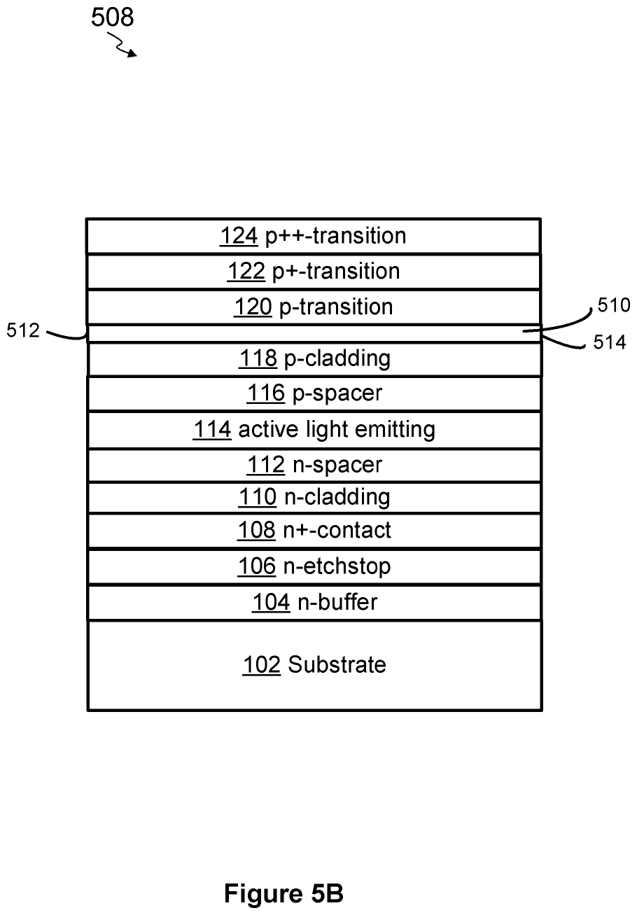

FIG. 5A is a cross-sectional view of an LED structure 500 with an oxide precursor layer 502 between the p-cladding layer 118 and the p-transition layer 120, in accordance with some embodiments. In some embodiments, the LED structure 500 includes a layer 502 composed of AlₓGa₁₋ₓAs (x is greater than or equal to 0.9 and less than 1). In some embodiments, the thickness of the layer 502 is about 1 nm to 100 nm. The rest of the structure of the LED structure is similar or the same as all the layers of the LED structure 100 as described in FIG. 1. In some embodiments, the layer 502 is located between the p-cladding layer 118 and the p-transition layer 120. In some embodiments, the layer 502 is used as a pre-cursor before a subsequent oxidation process. In some embodiments, the layer 502 is doped with Mg at a carrier concentration of 1.0×10¹⁷ to 9.0×10¹⁸ cm⁻³.

FIG. 5B is a cross-sectional view of an LED structure 508 with an oxide layer between the p-cladding layer 118 and the p-transition layer 120, in accordance with some embodiments. In some embodiments, the LED structure 508 includes an oxide layer 510. In some embodiments, the oxide layer 510 is composed of AlₓOGa₁₋ₓAs (xis greater than or equal to 0.9 and less than 1). The rest of the structure of the LED structure 508 is similar or the same as all the layers of the LED structure 100 as described in FIG. 1. In some embodiments, the layer 510 is located between the p-cladding layer 118 and the p-transition layer 120. In some embodiments, the oxide layer 510 is formed from an oxidation process after all the layers of the LED structure 500 as described in FIG. 5A is formed.

In some embodiments, a subsequent oxidation process is applied after all the epitaxial layers of the LED structure 500 are formed. In some embodiments, the oxidation process is a wet oxidation. In some embodiments, the wet oxidation is conducted in a wet oxygen oxidation furnace. In one example, the wet oxygen oxidation furnace is VF3000 VCSEL furnace from Koyo Thermo Systems. In some embodiments, a nitrogen gas is used as carrier gas at a flow rate of 1 liter per minute. Oxygen is obtained from the water heated at around 98° C. in the wet oxygen oxidation furnace. In some embodiments, the wet oxidation uses an ambient temperature from 380° C. to 500° C., and a time of equal to or under 2 hours. The oxidation is a controlled oxidation on the side wall of the LED structure 500. Since all the other layers in the LED structure 500 are not reactive to the oxidation process, the side wall of the layer 502 is oxidized. The oxidation process is stopped when the desired oxidation depth of the side wall of the layer 502 is reached. In some embodiments, the preferred oxidation depth of the side wall of the layer 502 is around one fourth of the lateral diameter of the layer 502. In some embodiments, the preferred oxidation depth of the side wall of the layer 502 is around one fifth of the lateral diameter of the layer 502. In some embodiments, the preferred oxidation depth of the side wall of the layer 502 is around one third of the lateral diameter of the layer 502.

In some embodiments, after the oxidation process, the oxide layer 510 composed of AlₓOGa₁₋ₓAs (x is greater than or equal to 0.9 and less than 1) is formed from the original layer 502 composed of AlₓGa₁₋ₓAs (x is greater than or equal to 0.9 and less than 1). In a preferred embodiment, the oxide layer 510 has AlₓOGa₁₋ₓAs (x is greater than or equal to 0.9 and less than 1) formed around the edge of the layer of 510, for example, 512 and 514, i.e., toward the side of the LED structure 508, while the center of the layer 510 remains less oxidized/or remains not oxidized. In some embodiments, all the other layers in the LED structure 500/508 other than the original layer 502 composed of AlₓGa₁₋ₓAs (x is greater than or equal to 0.9 and less than 1) are resistant to the oxidation process and remain unoxidized.

Non-radiative electron-hole pair recombination at the side surfaces, especially, defect sites, of the p-cladding layer 118 and p-transition layer 120 may cause additional energy loss, such as heat, and reduce the light emission efficiency. The introduction of the oxide layer 510 between the p-cladding layer 118 and p-transition layer 120 can reduce the surface non-radiative recombination and improve the light emission efficiency of the LED device. Specifically, when the oxidation mostly happens at the edge of the layer 510, the formed oxide layer can reduce or eliminate the non-radiative recombination at the side surfaces or edge, such as, locations 512 and 514, around the layer 510. The main current of an LED is in a vertical direction and there are some current diffusions to the side of the LED in the electric current flowing process. In some embodiments, when the oxidation mostly happens at the edge of the layer 510, the formed oxide layer can reduce the lateral diffusion of the electric current to the edge, and confine the electric current to the central portion of the LED device formed from the LED structure 508, therefore, increasing the effective electric current density and improving the LED light emission efficiency. In some embodiments, the light emission efficiency is at least 20%. In some embodiments, the light emission efficiency is at least 30%. In some embodiments, the light emission efficiency is at least 40%. In some embodiments, the light emission efficiency is at least 50%. In some embodiments, the light emission efficiency is at least 60%.

In some other embodiments, the precursor layer or the oxidized layer is formed between the n-cladding layer 110 and the n-spacer layer 112. In yet some other embodiments, the precursor layer or the oxidized layer is formed between the p-cladding layer 118 and the p-transition layer 120.

In some embodiments, the pre-cursor layers or the oxidized layers shown in any one of the FIGS. 2A-5B or mentioned above can be included in an LED structure in any combination. For example, the LED structure can include one to four layers of the pre-cursor layers or the oxidized layers at different positions of the LED structure as mentioned above. In another example, the LED structure can include one to six layers of the pre-cursor layers or the oxidized layers at different positions of the LED structure as mentioned above.

In some embodiments, it is preferred to have the oxide layer (s) formed on the n-side of the LED structure. In some processes, it is possible but difficult to introduce any Arsenic containing layers on the p-side of the LED structure that may impact the stability of the device.

In some embodiments, the substrate 102, for example, the GaAs substrate, from which the rest of the LED structure layers are grown from, by an epitaxial process, has a good lattice matching property with the epitaxial layers, but has some undesirable characteristics as the final LED device substrate, such as a low conductivity to support circuit structures, and a high light absorption to the light emitted from an LED. Therefore, the original substrate 102 may be removed from the final LED structure and a new substrate for better supporting circuit structures may be needed to form the LED device.

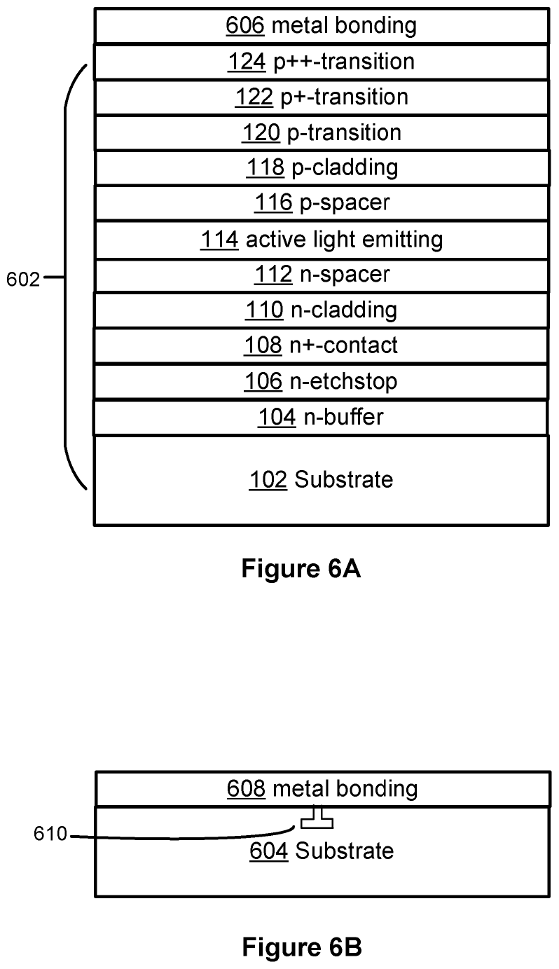

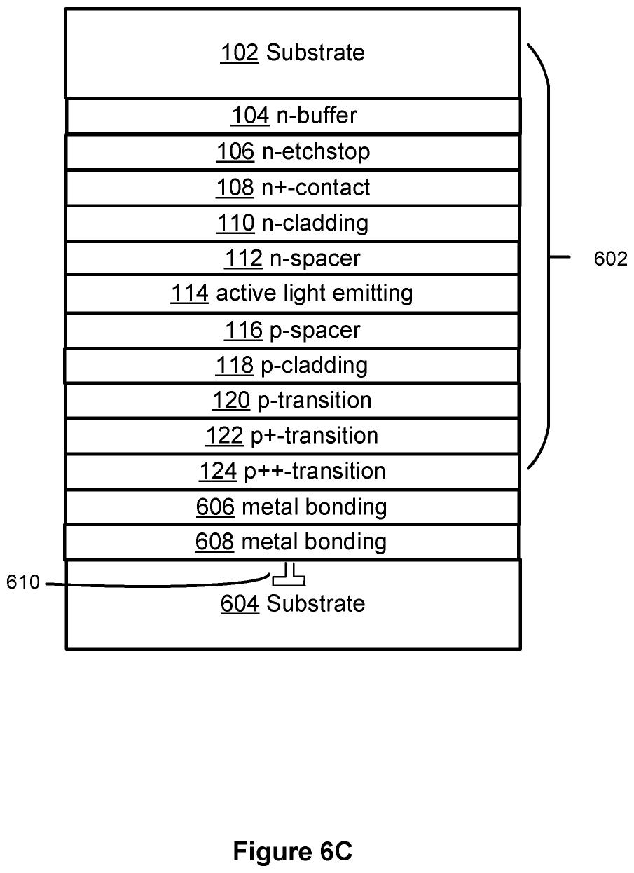

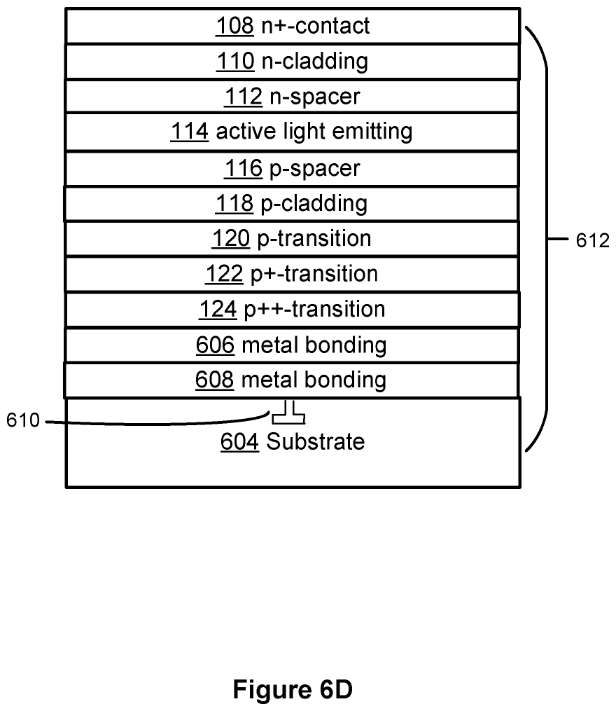

FIGS. 6A-6D illustrate a fabrication process utilizing a one-time transfer process to form an LED structure 612 with a supporting substrate 604 with integrated circuits, in accordance with some embodiments. In some embodiments, the initial color LED structure 602 shown in FIGS. 6A and 6C has the same or similar structures as any one of the LED structures described in FIGS. 1-5B, or any combination thereof. For illustration purpose, the exemplary structure 100 described in FIG. 1 is shown in FIGS. 6A-6D as the LED structure 602. Other color LED structures such as 200, 208, 300, 308, 400, 408, 500, and 508 described in FIG. 2A-5B, or any other LED structure embodiments described herein can be shown in FIGS. 6A-6D as the LED structure 602 in the same P to N direction as the LED structure 100.

In some embodiments, in FIG. 6A, a metal bonding layer 606 is deposited on the p-side of the LED structure 602, for example, above the p⁺⁺-transition layer 124.

In some embodiments, in FIG. 6B, a metal bonding layer 608 is deposited on a supporting substrate 604 with integrated circuit. In some embodiments, the supporting substrate 604 is the substrate on which the array of individual driver circuits 610 is fabricated. Each driver circuit 610 is a pixel driver. In some instances, the pixel drivers are thin-film transistor pixel drivers or silicon CMOS pixel drivers. In a preferred embodiment, the substrate 604 is a Silicon substrate. In another embodiment, the supporting substrate 604 is a transparent substrate, for example, a glass substrate. Other example substrates include GaAs, GaP, InP, SiC, ZnO, and sapphire substrates. The driver circuits 610 form individual pixel drivers to control the operation of the individual color LED device formed from the LED structure 602. The circuitry on substrate 604 includes contacts to each individual pixel driver 610 and also a ground contact.

In some embodiments, the LED structure 602 also has two types of contacts: P electrodes or anodes (not shown in FIGS. 6A-6D), which are connected to both the p-side of the LED structure 602 and the respective driver circuit 610; and N electrodes or cathodes (not shown in FIGS. 6A-6D), which are connected to both the n-side of the LED structure 602 and the ground (i.e., the common electrode).

In some embodiments, the driver circuit 610, for example, a pixel driver, includes a number of transistors and capacitors (not shown in FIGS. 6A-6D). The transistors include a driving transistor connected to a voltage supply, and a control transistor configured with its gate connected to a scan signal bus line. The capacitors include a storage capacitor used maintain the gate voltage of the driving transistor during the time that the scan signal is setting other pixels.

In some embodiments, in FIG. 6C, the LED structure 602 and the supporting substrate 604 are bonded together by the bonding of the metal bonding layers 606 and 608. The combined metal bonding layer 606 and 608 may include ohmic contact layers in addition to the metal bonding layers. In some embodiments, the thickness of the combined metal bonding layer 606 and 608 is about 0.1 micron to about 3 microns. In some instances, two metal layers, such as 606 and 608 are included in the metal bonding layer. One of the metal layers is deposited on the LED structure 602. A counterpart metal bonding layer is deposited on the supporting substrate 604. In some embodiments, compositions for the combined metal bonding layer include Au—Au bonding, Au—Sn bonding, Au—In bonding, Ti—Ti bonding, Cu—Cu bonding, or a mixture thereof. For example, if Au—Au bonding is selected, the two layers of Au respectively need a Cr coating as an adhesive layer, and Pt coating as an anti-diffusion layer. And the Pt coating is between the Au layer and the Cr layer. The Cr and Pt layers are positioned on the top and bottom of the two bonded Au layers. In some embodiments, when the thicknesses of the two Au layers are about the same, under a high pressure and a high temperature, the mutual diffusion of Au on both layers bonds the two layers together. Eutectic bonding, thermal compression bonding, and transient liquid phase (TLP) bonding are example techniques that may be used.

As shown in FIG. 6C, the p-side of the LED structure 602, for example, the p⁺⁺-transition layer 124, is bonded with the supporting substrate 604 through the bonding metal layers 606 and 608. In some embodiments, the P-electrode (not shown in FIGS. 6A-6D) connects to the p⁺⁺-transition layer 124 through the combined metal bonding layer 606 and 608. In some embodiments, the P-electrode is connected through the metal bonding layer 606 and 608 to the driver circuit 610. In some embodiments, the metal bonding layer can function as an electrical contact layer.

In some embodiments, the substrate 102 of the LED structure 602 is then removed after the bonding step, for example, by a laser lift-off process or wet chemical etching, leaving the LED structure 612 shown in FIG. 6D including the supporting substrate 604, the combined metal bonding layer 606 and 608, and the remaining layers of the LED structure 602 without the substrate 102. In some embodiments, the n-buffer layer 104 is also removed with the substrate 102. In some embodiments, the n-buffer layer 104 and the n-etch stop layer 106 are also removed with the substrate 102 in the same or different process.

In FIG. 6D, the n-side of the LED structure 612, for example, n⁺-contact layer 108, is the side where the light from the color LED device formed from the LED structure 612 is emitted out.

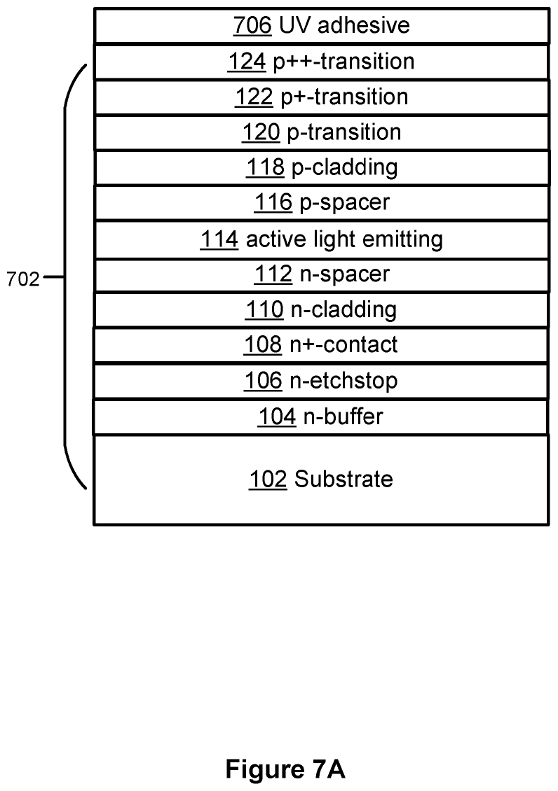

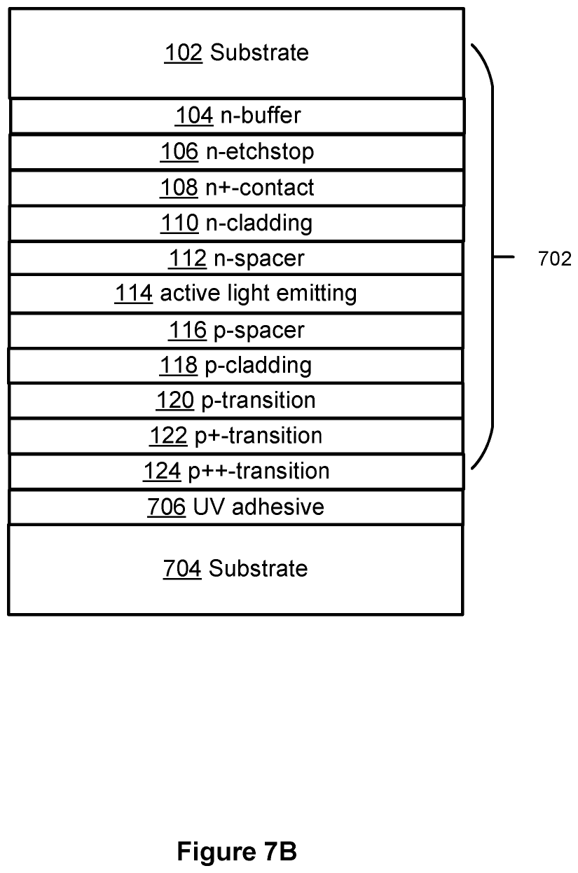

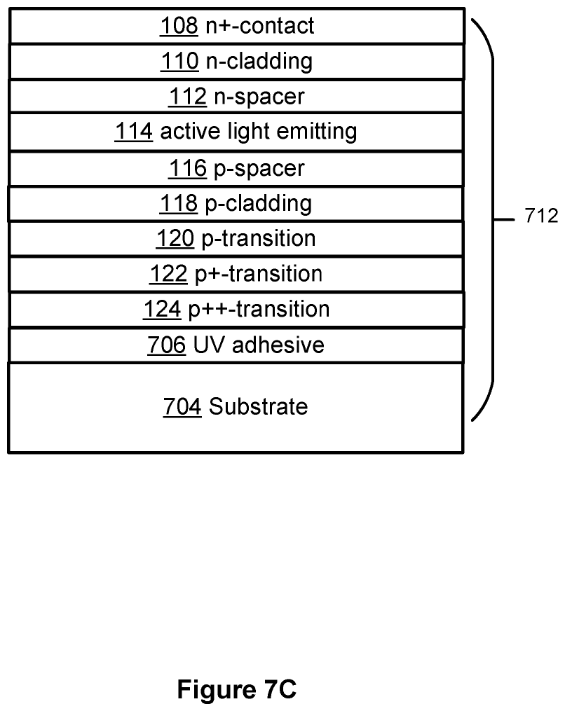

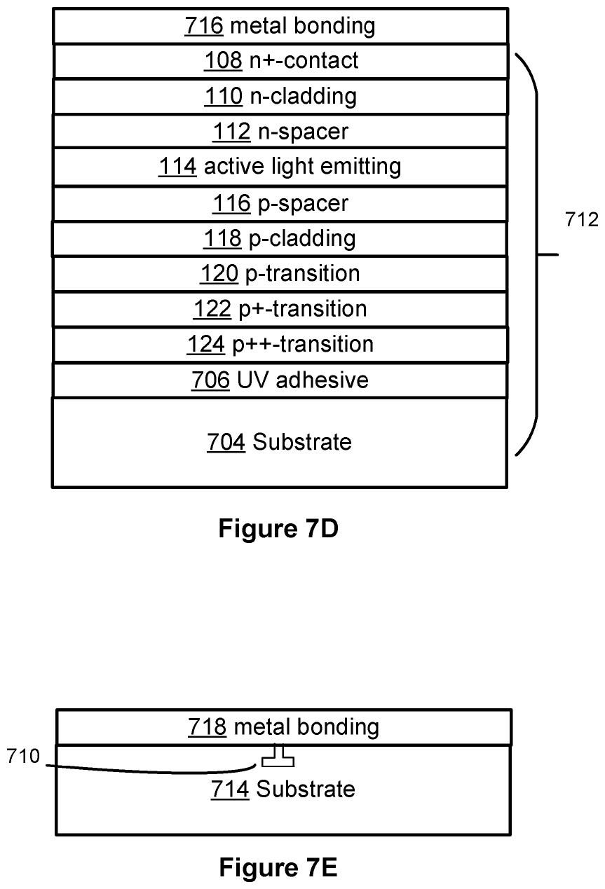

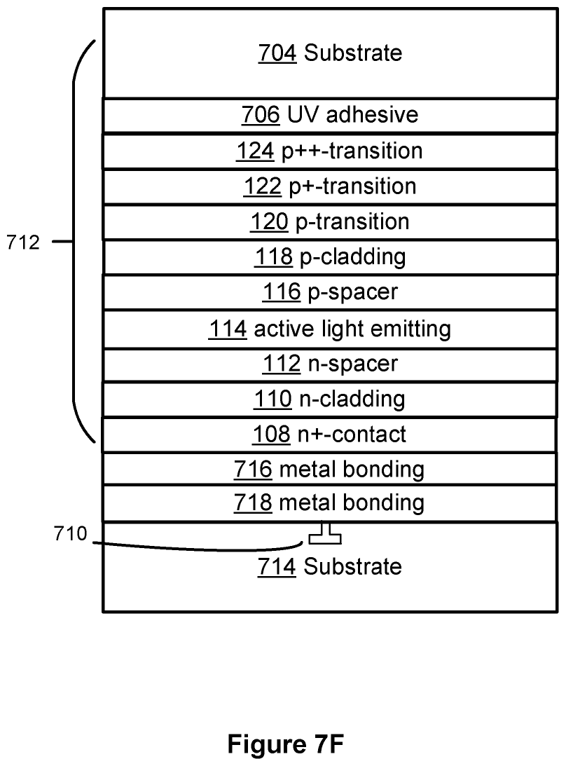

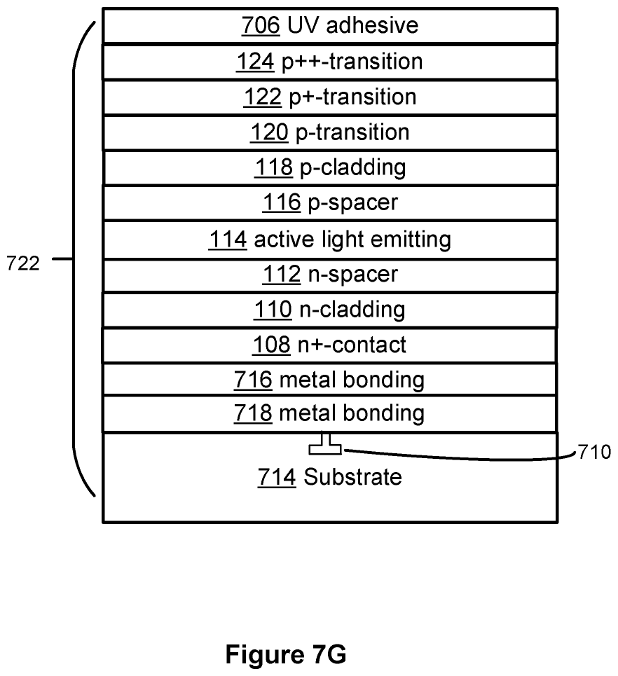

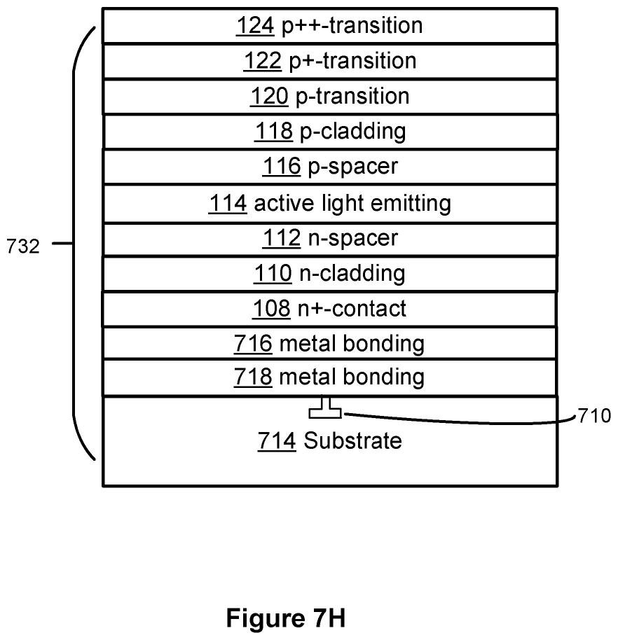

FIGS. 7A-7H illustrate a fabrication process utilizing a two-time transfer process to form an LED structure 732 with a supporting substrate 714 with integrated circuits, in accordance with some embodiments. In some embodiments, the initial color LED structure 702 has the same or similar structures as any one of the LED structures described in FIGS. 1-5B, or any combination thereof. For illustration purpose, the exemplary structure 100 described in FIG. 1 is shown in FIGS. 7A-7H as the LED structure 702. Other color LED structures such as 200, 208, 300, 308, 400, 408, 500, and 508 described in FIGS. 2-5, or any other LED structure embodiments described herein can be shown in FIGS. 7A-7H as the LED structure 702 in the same P to N direction as the LED structure 100.

In some embodiments, in FIG. 7A, an Ultraviolet (UV) curable adhesive layer 706 is deposited on the p-side of the LED structure 702, for example, above the p⁺⁺-transition layer 124. The UV curable adhesive materials comprise one or more polymers selected from the group consisting of bonding adhesive Micro Resist BCL-1200, SU-8, photosensitive polyimide (PSPI), PermiNex, Benzocyclobutene (BCB), and transparent plastic (resin) including spin-on glass (SOG), or any combination thereof.

In some embodiments, in FIG. 7B, an intermediate substrate 704 and the LED color structure 702 is bonded together by the UV curable adhesive layer 706. In some embodiments, the intermediate substrate 704 is made of sapphire. The intermediate substrate is needed to hold the LED structure on the substrate since the LED chip is thin and difficult to transfer. In another embodiment, the intermediate substrate 704 is a transparent substrate, for example, a glass substrate. Other example substrates include GaAs, GaP, InP, SiC, and ZnO substrates. In some embodiments, the UV curable adhesive layer 706 is cured by shining a UV light through the intermediate substrate 704 on the UV curable adhesive layer 706, therefore forming a high strength bond between the intermediate substrate 704 and the LED color structure 702. As shown in FIG. 7B, the p-side of the LED structure 702, for example, the p⁺⁺-transition layer 124, is bonded with the intermediate substrate 704 through the UV curable adhesive layer 706.

In an alternative embodiments, the UV curable adhesive is deposited on the intermediate substrate 704 for bonding. In some embodiments, the UV curable adhesive is deposited on both the p-side of the LED color structure 702 and on the surface of the intermediate substrate 704 for bonding.

As shown in FIG. 7C, in some embodiments, the substrate 102 of the LED structure 702 is then removed after the bonding step, for example, by a laser lift-off process or wet chemical etching, leaving the LED structure 712 shown in FIG. 7C including the intermediate substrate 704, the UV curable adhesive layer 706, and the remaining layers of the LED structure 702 without the substrate 102. In some embodiments, the n-buffer layer 104 is also removed with the substrate 102. In some embodiments, as shown in FIG. 7C, the n-buffer layer 104 and the n-etch stop layer 106 are also removed with the substrate 102.

In some embodiments, in FIG. 7D, a metal bonding layer 716 is deposited on the n-side of the LED structure 712, for example, above the n⁺-contact layer 108.

In some embodiments, in FIG. 7E, a metal bonding layer 718 is deposited on a supporting substrate 714 with integrated circuit. In some embodiments, the supporting substrate 714 is the substrate on which the array of individual driver circuits 710 is fabricated. Each driver circuit 710 is a pixel driver. In some instances, the pixel drivers are thin-film transistor pixel drivers or silicon CMOS pixel drivers. In a preferred embodiment, the substrate 714 is a Silicon substrate. In another embodiment, the supporting substrate 714 is a transparent substrate, for example, a glass substrate. Other example substrates include GaAs, GaP, InP, SiC, ZnO, and sapphire substrates. The driver circuits 710 form individual pixel drivers to control the operation of the individual color LED device formed from the LED structure 712. The circuitry on substrate 714 includes contacts to each individual pixel driver 710 and also a ground contact.

In some embodiments, the LED structure 712 also has two types of contacts: P electrodes or anodes (not shown in FIGS. 7A-7H), which are connected to both the p-side of the LED structure 712 and the respective driver circuit 710; and N electrodes or cathodes (not shown in FIGS. 7A-7H), which are connected to both the n-side of the LED structure 712 and the ground (i.e., the common electrode).

In some embodiments, the driver circuit 710, for example, a pixel driver, includes a number of transistors and capacitors (not shown in FIGS. 7A-7H). The transistors include a driving transistor connected to a voltage supply, and a control transistor configured with its gate connected to a scan signal bus line. The capacitors include a storage capacitor used maintain the gate voltage of the driving transistor during the time that the scan signal is setting other pixels.

In some embodiments, in FIG. 7F, the LED structure 712 and the supporting substrate 714 are bonded together by the bonding of the metal bonding layers 716 and 718. The combined metal bonding layer 716 and 718 may include ohmic contact layers in addition to the metal bonding layers. In some embodiments, the thickness of the combined metal bonding layer 716 and 718 is about 0.1 micron to about 3 microns. In some instances, two metal layers, such as 716 and 718 are included in the metal bonding layer. One of the metal layers is deposited on the LED structure 712. A counterpart metal bonding layer is deposited on the supporting substrate 714. In some embodiments, compositions for the combined metal bonding layer include Au—Au bonding, Au—Sn bonding, Au—In bonding, Ti—Ti bonding, Cu—Cu bonding, or a mixture thereof. For example, if Au—Au bonding is selected, the two layers of Au respectively need a Cr coating as an adhesive layer, and Pt coating as an anti-diffusion layer. And the Pt coating is between the Au layer and the Cr layer. The Cr and Pt layers are positioned on the top and bottom of the two bonded Au layers. In some embodiments, when the thicknesses of the two Au layers are about the same, under a high pressure and a high temperature, the mutual diffusion of Au on both layers bonds the two layers together. Eutectic bonding, thermal compression bonding, and transient liquid phase (TLP) bonding are example techniques that may be used.

As shown in FIG. 7F, the n-side of the LED structure 712, for example, the n⁺-contact layer 108, is bonded with the supporting substrate 714 through the bonding metal layers 716 and 718. In some embodiments, the P-electrode (not shown in FIGS. 7A-7H) connects to the p⁺⁺-transition layer 124 or the N-electrode (not shown in FIGS. 7A-7H) connects to the n⁺-contact layer 108 through the combined metal bonding layer 716 and 718. In some embodiments, the P-electrode or the N-electrode is connected through the metal bonding layer 716 and 718 to the driver circuit 710. In some embodiments, the metal bonding layer can function as an electrical contact layer.

In some embodiments, in FIG. 7G, the intermediate substrate 704 of the LED structure 712 is then removed after the bonding step, for example, by a laser lift-off process or wet chemical etching, leaving the LED structure 722 shown in FIG. 7G including the supporting substrate 714, the combined metal bonding layer 716 and 718, and the remaining layers of the LED structure 712 without the intermediate substrate 704.

In some embodiments, the UV curable adhesive layer 706 of the LED structure 722 is then removed after the intermediate substrate 704 is removed, for example, by a chemical etching or laser lift-off, leaving the LED structure 732 shown in FIG. 7H including the supporting substrate 714, the combined metal bonding layer 716 and 718, and the remaining layers of the LED structure 722 without the UV curable adhesive layer 706.

In FIG. 7H, the p-side of the LED structure 732, for example, p⁺⁺-transition layer 124, is the side where the light from the color LED device formed from the LED structure 732 is emitted out.

In some embodiments, when the p-side is the side where light from an LED device is emitted out, a transparent electrode layer to the light of the LED, such as an Indium tin oxide (ITO) layer, can be deposited on the top of the p-side layers (not shown in FIGS. 7A-7H) of the LED to allow light to transmit further through the transparent electrode. In some embodiments, the transparent electrode is a p-electrode. In some embodiments, the material of the top electrode layer is selected from the group consisting of graphene, ITO, Aluminum-Doped Zinc Oxide (AZO), and Fluorine doped Tin Oxide (FTO). In general, it is hard for an ITO layer to form an ohmic contact with the n-side of an LED. The electrode layer used for the n-side of an LED is made of metal which may not be transparent to the light emitted from the LED. Compared to one-time transfer as described in FIGS. 6A-6D, the two-time transfer described in FIGS. 7A-7H forms a p-side emission LED that would allow better integration and easy fabrication of a transparent electrode at the top of the LED device.

In some embodiments, the p-side layers include the p-type layers such as the p-spacer layer 116, p-cladding layer 118, p-transition layer 120, p⁺-transition layer 122, and p⁺⁺-transition layer 124. In some embodiments, the n-side layers include the n-type layers such as the n-spacer layer 112, n-cladding layer 110, and n⁺-contact layer 108.

In some embodiments, the thickness of the p-side layers of the LED structure 732 is thinner than the thickness of the n-side layers of the LED structure 732. In some embodiments, the thickness of the p-side layers of the LED structure 732 is thinner than the thickness of the n-side layers of the LED structure 732 as a result of the UV curable adhesive layer removal. In some embodiments, the reduction of the thickness of the p-side layers of the LED can limit the lateral diffusion of the electric current, make the current flow focused on the vertical direction of the LED, and enhance the light emission efficiency.

In some embodiments, the ratio of the total thickness of the p-type layers to the total thickness of the n-type layers is 0.025 to 100. In some preferred embodiments, the ratio of the total thickness of the p-type layers to the total thickness of the n-type layers is 1.5 to 2.

In some embodiments, the ratio of the thickness of the p-type conductive layers including the p-transition layer 120, p⁺-transition layer 122, and p⁺⁺-transition layer 124 to the thickness of the n-type conductive layer(s) including the n⁺-contact layer 108 is 0.025 to 100. In some preferred embodiments, the ratio of the thickness of the p-type conductive layers including the p-transition layer 120, p⁺-transition layer 122, and p⁺⁺-transition layer 124 to the thickness of the n-type conductive layer(s) including the n⁺-contact layer 108 is 1.5 to 2.

In some embodiments, the ratio of the thickness of the p-cladding layer 118 to the total thickness of the one or more of p-transition layer 120, p⁺-transition layer 122, and p⁺⁺-transition layer 124 is 0.02 to 120. In some preferred embodiments, the ratio of the thickness of the p-cladding layer 118 to the total thickness of the one or more of p-transition layer 120, p⁺-transition layer 122, and p⁺⁺-transition layer 124 is 1 to 2.5.

Various design aspects of the single color or multi-color LED device, such as the dimensions of the layers (e.g., width, length, height, and cross-sectional area of each layer), the dimension of the electrodes, size, shape, spacing, and arrangement of the two or more LED structures, the two or more active light emitting layers, bonding layers, the conductive layers, other reflection layers, and the configuration between the integrated circuits, pixel driver and electrical connections are selected (e.g., optimized using a cost or performance function) for obtaining the desired LED characteristics. LED characteristics that vary based on the above design aspects include, e.g., size, materials, cost, fabrication efficiency, light emission efficiency, power consumption, directivity, luminous intensity, luminous flux, color, spectrum and spatial radiation pattern.

Further embodiments also include various subsets of the above embodiments including embodiments in FIGS. 1-7H combined or otherwise re-arranged in various embodiments.

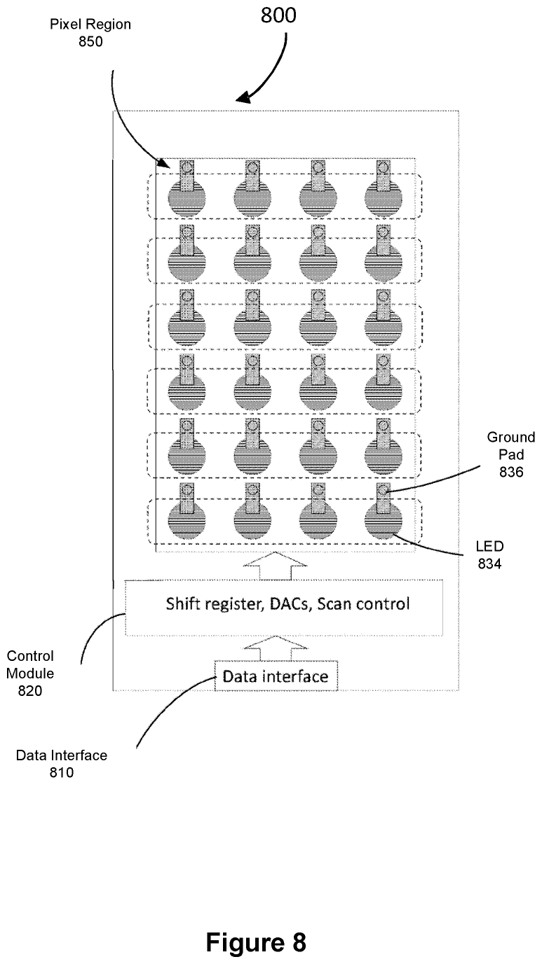

FIG. 8 is a top view of a micro LED display panel 800, in accordance with some embodiments. The display panel 800 includes a data interface 810, a control module 820 and a pixel region 850. The data interface 810 receives data defining the image to be displayed. The source(s) and format of this data will vary depending on the application. The control module 820 receives the incoming data and converts it to a form suitable to drive the pixels in the display panel. The control module 820 may include digital logic and/or state machines to convert from the received format to one appropriate for the pixel region 840, shift registers or other types of buffers and memory to store and transfer the data, digital-to-analog converters and level shifters, and scan controllers including clocking circuitry.

The pixel region 850 includes an array of mesas (not separately shown from the LED 834 in FIG. 8) including pixels. The pixels include micro LEDs, such as a single color or multi-color LED 834, integrated with pixel drivers, for example as described above. An array of micro-lens (not separately shown from the LED 834 in FIG. 8) covers the top of the array of mesas. In this example, the display panel 800 is a color RGB display panel. It includes red, green and blue pixels. Within each pixel, the LED 834 is controlled by a pixel driver. The pixel makes contact to a supply voltage (not shown in FIG. 8) and ground via a ground pad 836, and also to a control signal, according to the embodiments shown previously. Although not shown in FIG. 8, the p-electrode of the LED 834 and the output of the driving transistor are electrically connected. The LED current driving signal connection (between p-electrode of LED and output of the pixel driver), ground connection (between n-electrode and system ground), the supply voltage Vdd connection (between source of the pixel driver and system Vdd), and the control signal connection to the gate of the pixel driver are made in accordance with various embodiments. Any of the micro-lens array disclosed herein can be implemented with the micro LED display panel 800.

FIG. 8 is merely a representative figure. Other designs will be apparent. For example, the colors do not have to be red, green and blue. They also do not have to be arranged in columns or stripes. As one example, apart from the arrangement of a square matrix of pixels shown in FIG. 8, an arrangement of hexagonal matrix of pixels can also be used to form the display panel 800.

In some applications, a fully programmable rectangular array of pixels is not necessary. Other designs of display panels with a variety of shapes and displays may also be formed using the device structures described herein. One class of examples is specialty applications, including signage and automotive. For example, multiple pixels may be arranged in the shape of a star or a spiral to form a display panel, and different patterns on the display panel can be produced by turning on and off the LEDs. Another specialty example is automobile headlights and smart lighting, where certain pixels are grouped together to form various illumination shapes and each group of LED pixels can be turned on or off or otherwise adjusted by individual pixel drivers.

Even the lateral arrangement of devices within each pixel can vary. In FIG. 1A, the LEDs and pixel drivers are arranged vertically, i.e., each LED is located on top of the corresponding pixel driver circuit. Other arrangements are possible. For example, the pixel drivers could also be located “behind”, “in front of”, or “beside” the LED.

Different types of display panels can be fabricated. For example, the resolution of a display panel can range typically from 8×8 to 3840×2160. Common display resolutions include QVGA with 320×240 resolution and an aspect ratio of 4:3, XGA with 1024×768 resolution and an aspect ratio of 4:3, D with 1280×720 resolution and an aspect ratio of 16:9, FHD with 1920×1080 resolution and an aspect ratio of 16:9, UHD with 3840×2160 resolution and an aspect ratio of 16:9, and 4K with $326×2160 resolution. There can also be a wide variety of pixel sizes, ranging from sub-micron and below to 10 mm and above. The size of the overall display region can also vary widely, ranging from diagonals as small as tens of microns or less up to hundreds of inches or more.

Different applications will also have different requirements for optical brightness and viewing angle. Example applications include direct viewing display screens, light engines for home/office projectors and portable electronics such as smart phones, laptops, wearable electronics, AR and VR glasses, and retinal projections. The power consumption can vary from as low as a few milliwatts for retinal projectors to as high as kilowatts for large screen outdoor displays, projectors, and smart automobile headlights. In terms of frame rate, due to the fast response (nanoseconds) of inorganic LEDs, the frame rate can be as high as KHz, or even MHz for small resolutions.

Further embodiments also include various subsets of the above embodiments including embodiments as shown in FIGS. 1-8 combined or otherwise re-arranged in various other embodiments.

Although the detailed description contains many specifics, these should not be construed as limiting the scope of the invention but merely as illustrating different examples and aspects of the invention. It should be appreciated that the scope of the invention includes other embodiments not discussed in detail above. For example, the approaches described above can be applied to the integration of functional devices other than LEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples also include Organic LED (OLED) devices. Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present invention can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present invention can be incorporated in software and/or firmware for controlling the hardware of a processing system, and for enabling a processing system to interact with other mechanisms utilizing the results of the present invention. Such software or firmware may include, but is not limited to, application code, device drivers, operating systems, and execution environments/containers.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

1-48. (canceled)

49. A micro light emitting diode (LED) chip structure, comprising:
a semiconductor substrate;
an electrical contact layer on the semiconductor substrate;
a first-type conductive layer on the electrical contact layer;
an active light emitting layer on the first-type conductive layer; and
a second-type conductive layer on the active light emitting layer,
wherein a surface of the micro LED chip structure close to the second-type conductive layer is obtained after a substrate layer is removed.

50. The micro LED chip structure according to claim 49, wherein a surface of the second-type conductive layer is obtained after an organic material layer is removed.

51. The micro LED chip structure according to claim 50, wherein the organic material layer is an ultraviolet (UV) curable bonding layer.

52. The micro LED chip structure according to claim 49, wherein a thickness of the second-type conductive layer is smaller than a thickness of the first-type conductive layer.

53. The micro LED chip structure according to claim 49, further comprising a second-type spacer layer between the active light emitting layer and the second-type conductive layer,
wherein the second-type spacer layer is used for forming a PN junction structure with the active light emitting layer and the first-type conductive layer, and
wherein the second-type conductive layer includes one or more second-type conductive transition layers.

54. The micro LED chip structure according to claim 49, wherein the first-type conductive layer is an N-type layer and the second-type conductive layer is a P-type layer, or wherein the first-type conductive layer is a P-type layer and the second-type conductive layer is an N-type layer.

55. The micro LED chip structure according to claim 49, wherein the semiconductor substrate is an integrated circuits (IC) substrate.

56. The micro LED chip structure according to claim 49, wherein the electrical contact layer is a metal bonding layer, and wherein the semiconductor substrate and the first-type conductive layer are bonded together through a bonding process.

57. The micro LED chip structure according to claim 49, further comprising a first-type cladding layer between the first-type conductive layer and the active light emitting layer.

58. The micro LED chip structure according to claim 57, further comprising an oxide layer within the first-type cladding layer or between the first-type conductive layer and the first-type cladding layer.

59. The micro LED chip structure according to claim 58, wherein material of the oxide layer is AlₓOGa₁₋ₓAs, and x is greater than or equal to 0.9 and less than 1.

60. The micro LED chip structure according to claim 49, further comprising a second-type cladding layer between the second-type conductive layer and the active light emitting layer.

61. The micro LED chip structure according to claim 60, further comprising an oxide layer within the second-type cladding layer or between the second-type conductive layer and the second-type cladding layer.

62. The micro LED chip structure according to claim 61, wherein material of the oxide layer is AlₓOGa₁₋ₓAs, and x is greater than or equal to 0.9 and less than 1.

63. The micro LED chip structure according to claim 49, wherein a ratio of a thickness of the second-type conductive layer to a thickness of the first-type conductive layer is 1.5 to 2.

64. The micro LED chip structure according to claim 60, wherein the second-type conductive layer includes one or more second-type conductive transition layers, and wherein a ratio of a thickness of the second-type cladding layer to a total thickness of the one or more second-type conductive transition layers is 1 to 2.5.

65. The micro LED chip structure according to claim 49, wherein the second-type conductive layer includes one or more second-type conductive transition layers,
wherein the one or more second-type conductive transition layers comprise sequentially a lower second-type conductive transition layer, a middle second-type conductive transition layer, and an upper second-type conductive transition layer in a direction from the semiconductor substrate to the first-type conductive layer, and
wherein a conductivity of the lower second-type conductive transition layer is less than that of the middle second-type conductive transition layer, and the conductivity of the middle second-type conductive transition layer is less than that of the upper second-type conductive transition layer.

66. An epitaxial structure for a micro light emitting diode (LED), comprising:
a semiconductor substrate;
an electrical conductive layer of a first conductivity type on the semiconductor substrate;
a cladding layer of the first conductivity type on the electrical conductive layer of the first conductivity type;
a first oxide layer within the cladding layer of the first conductivity type or between the electrical conductive layer of the first conductivity type and the cladding layer of the first conductivity type;
an active light emitting layer on the cladding layer of the first conductivity type;
a cladding layer of a second conductivity type on the active light emitting layer; and
an electrical conductive layer of the second conductivity type on the cladding layer of the second conductivity type.

67. The epitaxial structure for a micro LED according to claim 66, further comprising a second oxide layer within the cladding layer of the second conductivity type or between the cladding layer of the second conductivity type and the electrical conductive layer of the second conductivity type.

68. An epitaxial structure for a micro light emitting diode (LED), comprising:
a semiconductor substrate;
an electrical conductive layer of a first conductivity type on the semiconductor substrate;
a cladding layer of the first conductivity type on the electrical conductive layer of the first conductivity type;
an active light emitting layer on the cladding layer of the first conductivity type;
a cladding layer of a second conductivity type on the active light emitting layer;
an electrical conductive layer of the second conductivity type on the cladding layer of the second conductivity type; and
a first oxide layer within the cladding layer of the second conductivity type or between the cladding layer of the second conductivity type and the electrical conductive layer of the second conductivity type.
